(19) United States
(12) Patent Application Publication
(10) Pub. No.: US 2022/0326614 A1
(43) Pub. Date: Oct. 13, 2022

(54) POSITIVE-TYPE PHOTOSENSITIVE RESIN COMPOSITION AND PARTITION WALL OF ORGANIC EL ELEMENT

(71) Applicant: SHOWA DENKO K.K., Tokyo (JP)

(72) Inventors: Yasuhiro ISHIDA, Tokyo (JP); Kentaro FURUE, Tokyo (JP); Yoshikazu ARAI, Tokyo (JP); Mitsuhiro IWASAKI, Tokyo (JP); Hideo HORIBE, Osaka-shi (JP)

(73) Assignee: SHOWA DENKO K.K., Tokyo (JP)

(21) Appl. No.: 17/596,046

(22) PCT Filed: Jun. 3, 2020
(86) PCT No.: PCT/JP2020/021996

§ 371 Date: Dec. 2, 2021

(30) Foreign Application Priority Data
Jun. 3, 2019 (JP) 2019-103688

(51) Int. Cl. G03F 7/039; H01L 51/00; H01L 51/52

(52) U.S. Cl. CPC G03F 7/039; H01L 51/0035; H01L 51/5284

(57) ABSTRACT

Provided is a high-sensitive photosensitive resin composition which contains a black colorant and by which development and pattern formation are possible even with a low exposure amount. A positive-type photosensitive resin composition according to one embodiment contains: a first resin (A) having a plurality of phenolic hydroxyl groups, at least some of which are protected with an acid-labile group; a second resin (B) having an epoxy group and a phenolic hydroxyl group; at least one colorant (C) selected from the group consisting of a black dye and a black pigment; and a photoacid generator (D).

### FIELD

The present invention relates to a positive photosensitive resin composition, and an organic EL element barrier rib, an organic EL element insulating film, and an organic EL element that use the same. More specifically, the present invention relates to a positive photosensitive resin composition containing a black colorant, and an organic EL element barrier rib, an organic EL element insulating film, and an organic EL element that use the same.

### BACKGROUND

In display devices, such as an organic EL display (OLED), barrier ribs are used in gaps of a coloring pattern in the display region or at the edge of the periphery of the display region, in order to improve display properties. In the manufacture of organic EL display devices, in order to ensure that pixels of an organic material do not touch each other, barrier ribs are first formed, then the pixels of an organic material are formed between the barrier ribs. Such barrier ribs are generally formed by photolithography using a photosensitive resin composition and have electrical insulating properties. More specifically, a photosensitive resin composition is applied onto a substrate using a coating device, and after volatile components are removed by heating, etc., the photosensitive resin composition is exposed to light through a mask. Next, unexposed parts, in the case of a negative tone, and exposed parts, in the case of a positive tone, are removed with a developer, such as an aqueous alkaline solution thereby developing the same. The obtained pattern is heat treated and barrier ribs (insulating film) are formed. Next, films of an organic material that emit one of three colors, i.e., red, green or blue, are formed between the barrier ribs using an inkjet method, etc., and pixels of the organic EL display device are formed.

Recently in this field, there is a demand for more compact display devices, and due to the diversification of the content displayed, there is a demand for higher pixel performance and higher resolution. For the purpose of increasing the contrast of a display device thereby improving visibility, colorants have been used to impart light shielding properties to the barrier ribs. However, in cases where light shielding properties are imparted to the barrier ribs, there is a tendency for the sensitivity of the photosensitive resin composition to decrease, and as a result, there is a risk that the time required for exposure would increase and productivity would decrease. Thus, a photosensitive resin composition used for forming barrier ribs containing a colorant is required to be highly sensitive.

Patent Literature 1 (JP 2001-281440 A) describes a composition in which titanium black is added to a positive tone radiation sensitive resin composition comprising an alkali-soluble resin and a quinone diazide compound as a radiation sensitive resin composition exhibiting high light shielding properties by heat treatment after exposure to light.

Patent Literature 2 (JP 2002-116536 A) describes a method for blackening barrier ribs using carbon black in a radiation sensitive resin composition comprising [A] an alkali-soluble resin, [B] a 1,2-quinone diazide compound, and [C] a colorant.

Patent Literature 3 (JP 2010-237310 A) describes a composition in which a heat sensitive dye is added to a positive tone radiation sensitive resin composition comprising an alkali-soluble resin and a quinone diazide compound as a radiation sensitive resin composition exhibiting light shielding properties by heat treatment after exposure to light.

### CITATION LIST

### Patent Literature

[PTL 1] JP 2001-281440 A

[PTL 2] JP 2002-116536 A

[PTL 3] JP 2010-237310 A

### SUMMARY

### Technical Problem

In order to sufficiently enhance the light shielding properties of a cured film of a photosensitive resin composition used for forming a colored barrier rib, a substantial amount of colorant is required. When such a substantial amount of colorant is used, as radiation applied to a coating of the photosensitive resin composition is absorbed by the colorant, the effective strength of the radiation in the coating is diminished, the photosensitive resin composition is not sufficiently exposed to light and as a result, pattern formability is impaired.

In the formation of barrier ribs for organic EL elements, it is important for the material that forms the barrier ribs to be highly sensitive from the viewpoint of productivity. However, when a black photosensitive resin composition containing a colorant is used, insufficient exposure occurs under normally used exposure conditions and it is necessary, for example, to extend exposure time, which is a factor in reducing productivity. Therefore, it is strongly desired to reduce the exposure dose of a photosensitive resin composition, thereby reducing the energy cost and increasing the throughput.

It is an object of the present invention to provide a highly sensitive photosensitive resin composition containing a black colorant which can be developed and patterned even at a low exposure dose.

### Solution to Problem

The present inventors have found that, by making a positive photosensitive resin composition a chemically amplified system comprising a first resin having a plurality of phenolic hydroxy groups, at least some of the plurality of phenolic hydroxy groups protected by an acid-decomposable group, and a specific second resin having an alkali-soluble functional group in combination, development and pattern formation are possible even at a low exposure dose, even though the composition contains a black colorant.

Specifically, the present invention includes the following aspects.

[1] A positive photosensitive resin composition comprising

a first resin (A) having a plurality of phenolic hydroxy groups, at least some of the plurality of phenolic hydroxy groups protected by an acid-decomposable group;

a second resin (B) having an epoxy group and a phenolic hydroxy group;

at least one colorant (C) selected from the group consisting of a black dye and a black pigment; and

a photoacid generator (D).

[2] The positive photosensitive resin composition according to [1], wherein the first resin (A) is an aqueous alkaline solution-soluble copolymer of a polymerizable monomer having a phenolic hydroxy group and an additional polymerizable monomer, the copolymer having a plurality of phenolic hydroxy groups, at least some of the plurality of phenolic hydroxy groups protected by the acid-decomposable group.
[3] The positive photosensitive resin composition according to [1] or [2], wherein the acid-decomposable group of the first resin (A) is a 1-alkoxyalkyl group.
[4] The positive photosensitive resin composition according to [2], wherein the first resin (A) has a structural unit represented by formula (3)

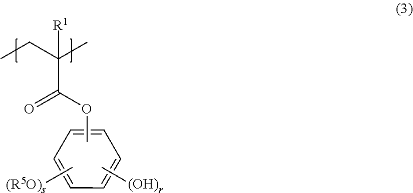

wherein in formula (3), R¹ is a hydrogen atom or an alkyl group having 1 to 5 carbon atoms, R⁵ is the acid-decomposable group, r is an integer from 0 to 5, s is an integer from 0 to 5, provided that r+s is an integer from 1 to 5, and the first resin (A) has at least one of the structural units in which s is an integer of 1 or more.
[5] The positive photosensitive resin composition according to any one of [2] to [4], wherein the first resin (A) has a structural unit represented by formula (2)

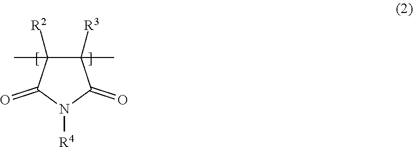

wherein in formula (2), R² and R³ are each independently a hydrogen atom, an alkyl group having 1 to 3 carbon atoms, a fully or partially fluorinated alkyl group having 1 to 3 carbon atoms, or a halogen atom, and R⁴ is a hydrogen atom, a linear alkyl group having 1 to 6 carbon atoms or a cyclic alkyl group having 4 to 12 carbon atoms, a phenyl group, or a phenyl group substituted with at least one selected from the group consisting of a hydroxy group, an alkyl group having 1 to 6 carbon atoms, and an alkoxy group having 1 to 6 carbon atoms.
[6] The positive photosensitive resin composition according to any one of [1] to [5], wherein 10 mol % to 95 mol % of the phenolic hydroxy groups of the first resin (A) are protected with the acid-decomposable group.
[7] The positive photosensitive resin composition according to any one of [1] to [6], wherein 5 mol % to 65 mol % of the phenolic hydroxy groups of the first resin (A) are protected with the acid-decomposable group with respect to the total of the alkali-soluble functional groups of the first resin (A) and the second resin (B).
[8] The positive photosensitive resin composition according to any one of [1] to [7], comprising 20% by mass to 90% by mass of the first resin (A) with respect to the total mass of the first resin (A) and the second resin (B).
[9] The positive photosensitive resin composition according to any one of [1] to [8], comprising 10 parts by mass to 150 parts by mass of the colorant (C) with respect to 100 parts by mass of the total of the first resin (A) and the second resin (B).
[10] The positive photosensitive resin composition according to any one of [1] to [9], comprising 0.1 parts by mass to 85 parts by mass of the photoacid generator (D) with respect to 100 parts by mass of the total of the first resin (A) and the second resin (B).
[11] The positive photosensitive resin composition according to any one of [1] to [10], wherein the optical density (OD value) of a cured coating of the positive photosensitive resin composition is 0.5 or more per μm of coating thickness.
[12] The positive photosensitive resin composition according to any one of [1] to [11], wherein the second resin (B) is a compound which is a reaction product of a compound having at least two epoxy groups per molecule and a hydroxybenzoic acid compound and has a structure represented by formula (5)

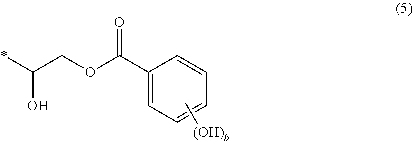

wherein in formula (5), b is an integer from 1 to 5, * represents a bonding site with the residue derived by removing an epoxy group involved in the reaction of the compound having at least two epoxy groups per molecule.
[13] The positive photosensitive resin composition according to [12], wherein the compound having at least two epoxy groups per molecule is a novolak epoxy resin.
[14] The positive photosensitive resin composition according to [12] or [13], wherein the hydroxybenzoic acid compound is a dihydroxybenzoic acid compound.
[15] The positive photosensitive resin composition according to any one of [1] to [14], wherein the epoxy equivalent of the second resin (B) is 300 to 1,800, and the photoacid generator (D) generates trifluoromethanesulfonic acid by light irradiation.
[16] An organic EL element barrier rib comprising a cured product of the positive photosensitive resin composition according to any one of [1] to [15].
[17] An organic EL element insulating film comprising a cured product of the positive photosensitive resin composition according to any one of [1] to [15].
[18] An organic EL element comprising a cured product of the positive photosensitive resin composition according to any one of [1] to [15].

### Advantageous Effects of Invention

According to the present invention, it is possible to provide a highly sensitive photosensitive resin composition containing a black colorant which can be developed and patterned even at a low exposure dose.

### DESCRIPTION OF EMBODIMENTS

The present invention will be described in detail below.

In the present disclosure, “alkali-soluble” and “aqueous alkaline solution-soluble” refer to a positive photosensitive resin composition or a component thereof, or a coating or cured coating of the positive photosensitive resin composition that can dissolve in an aqueous alkaline solution, for example, an aqueous solution of 2.38% by mass of tetramethylammonium hydroxide. “Alkali-soluble functional group” refers to a group that imparts such alkali-solubility to a positive photosensitive resin composition or a component thereof, or a coating or cured coating of the positive photosensitive resin composition. Examples of the alkali-soluble functional group include a phenolic hydroxy group, a carboxy group, a sulfo group, a phosphoric acid group, an acid anhydride group and a mercapto group.

In the present disclosure, “acid-decomposable group” refers to a group which decomposes (is deprotected) and generates an alkali-soluble functional group in the presence of an acid, by heating if necessary.

In the present disclosure, “radical polymerizable functional group” refers to one or more ethylenically unsaturated groups.

In the present disclosure, “(meth)acrylic” refers to acrylic or methacrylic, “(meth)acrylate” refers to acrylate or methacrylate, and “(meth)acryloyl” refers to acryloyl or methacryloyl.

In the present disclosure, the number average molecular weight (Mn) and the weight average molecular weight (Mw) of a resin or polymer refers to a value converted by standard polystyrene measured by gel permeation chromatography (GPC).

A positive photosensitive resin composition according to one embodiment comprises a first resin (A) having a plurality of phenolic hydroxy groups, at least some of the plurality of phenolic hydroxy groups protected by an acid-decomposable group; a second resin (B) having an epoxy group and a phenolic hydroxy group; at least one colorant (C) selected from the group consisting of a black dye and a black pigment; and a photoacid generator (D).

In one embodiment, the positive photosensitive resin composition comprises 10% by mass to 80% by mass, preferably 20% by mass to 65% by mass, and more preferably 30% by mass to 50% by mass of the first resin (A), with respect to 100% by mass of the solid content. When the content of the first resin (A) is 10% by mass or more with respect to 100% by mass of the solid content, a chemical amplification function can be imparted to the photosensitive resin composition to achieve high sensitivity. When the content of the first resin (A) is 80% by mass or less with respect to 100% by mass of the solid content, the residual amount of unreacted acid-decomposable groups can be reduced, and the solubility of exposed parts can be enhanced to achieve high sensitivity. In the present disclosure, “solid content” refers to a total mass of components including a first resin (A), a second resin (B), a colorant (C), a photoacid generator (D), a dissolution accelerator (E), and an optional component (F), and excluding a solvent (G).

In one embodiment, the positive photosensitive resin composition comprises 5% by mass to 50% by mass, preferably 10% by mass to 40% by mass, and more preferably 15% by mass to 30% by mass of the second resin (B), with respect to 100% by mass of the solid content. When the content of the second resin (B) is 5% by mass or more with respect to 100% by mass of the solid content, dissolution of exposed parts can be promoted to achieve high sensitivity, and stability and durability of a coating after heat curing can be secured. When the content of the second resin (B) is 50% by mass or less with respect to 100% by mass of the solid content, the solubility of unexposed parts can be suppressed to be low and the residual film ratio can be kept high.

In one embodiment, the positive photosensitive resin composition comprises 20% by mass to 90% by mass, preferably 35% by mass to 80% by mass, and more preferably 50% by mass to 75% by mass of the first resin (A), with respect to the total mass of the first resin (A) and the second resin (B). By setting the content of the first resin (A) to 20% by mass or more, a chemical amplification function can be imparted to the photosensitive resin composition to achieve high sensitivity. By setting the content of the first resin (A) to 90% by mass or less, the solubility of exposed parts can be enhanced to achieve high sensitivity.

### First Resin (A)

The first resin (A) is not particularly limited as long as it has a plurality of phenolic hydroxy groups and at least some of the plurality of phenolic hydroxy groups are protected with an acid-decomposable group. The phenolic hydroxy group is an alkali-soluble functional group, and some of the phenolic hydroxy groups are protected with an acid-decomposable group, so that the alkali solubility before exposure of the first resin (A) is suppressed. The first resin (A) may have an alkali-soluble functional group other than a phenolic hydroxy group, and such an alkali-soluble functional group may be protected with an acid-decomposable group as with a phenolic hydroxy group. In the presence of an acid generated at the time of exposure, by carrying out post exposure bake (PEB) if necessary, decomposition (deprotection) of the acid-decomposable group is promoted, and a phenolic hydroxy group is regenerated. This promotes alkali dissolution of the first resin (A) at exposed parts during development. The first resin (A) may have an alkali-soluble functional group other than a phenolic hydroxy group, such as a carboxy group, a sulfo group, a phosphoric acid group, an acid anhydride group, and a mercapto group. The first resin

(A) may be used alone or in combination of two or more thereof. For example, the first resin (A) may be a combination of two or more of resins, which are different in the constitutional unit of the polymer, the acid-decomposable group, the protection ratio of the phenolic hydroxy groups, or a combination thereof.

<Protection of Phenolic Hydroxy Group with Acid-Decomposable Group>

The first resin (A) can be obtained by protecting some of phenolic hydroxy groups of a base resin (a) having a plurality of phenolic hydroxy groups with an acid-decomposable group. The first resin (A) having a phenolic hydroxy group protected with an acid-decomposable group has a partial structure of Ar—O—R, wherein Ar represents an aromatic ring derived from a phenol, and R represents the acid-decomposable group.

The acid-decomposable group is a group which decomposes (is deprotected) and generates an alkali-soluble functional group in the presence of an acid, by heating if necessary. Specifically, examples thereof include a group having a tertiary alkyl group, such as a tert-butyl group, a 1,1-dimethyl-propyl group, a 1-methylcyclopentyl group, a 1-ethylcyclopentyl group, a 1-methylcyclohexyl group, a 1-ethylcyclohexyl group, a 1-methyladamantyl group, a 1-ethyladamantyl group, a tert-butoxycarbonyl group, and a 1,1-dimethyl-propoxycarbonyl group; a silyl group, such as a trimethylsilyl group, a triethylsilyl group, a t-butyldimethylsilyl group, a triisopropylsilyl group, and a t-butyldiphenylsilyl group; and a group represented by formula (7)

—CR⁶R⁷—O—R⁸ (7)

wherein in formula (7), R⁶ and R⁷ are each independently a hydrogen atom, or a linear or branched alkyl group having 1 to 4 carbon atoms, and R⁸ is a linear, branched or cyclic alkyl group having 1 to 12 carbon atoms, an aralkyl group having 7 to 12 carbon atoms, or an alkenyl group having 2 to 12 carbon atoms, and one of R⁶ and R⁷, and R⁸ may be bonded to form a ring structure. The group represented by formula (7) forms an acetal structure or a ketal structure together with an oxygen atom derived from a phenolic hydroxy group. These acid-decomposable groups may be used alone or in combination of two or more thereof. The number of ring members in the ring structure is preferably 3 to 10. R⁶, R⁷ and R⁸ may be substituted with a halogen atom selected from the group consisting of fluorine, chlorine, bromine and iodine.

Since a positive photosensitive resin composition having high sensitivity even at a low exposure dose can be obtained, the acid-decomposable group is preferably a group represented by formula (7). It is more preferable that R⁶ and R⁷ be each independently a hydrogen atom or a linear or branched alkyl group having 1 to 4 carbon atoms. It is more preferable that R⁸ be a linear, branched or cyclic alkyl group having 1 to 12 carbon atoms. R⁸ may be substituted with a halogen atom selected from the group consisting of fluorine, chlorine, bromine and iodine. Examples of such an acid-decomposable group include a 1-alkoxyalkyl group. Examples of the 1-alkoxyalkyl group include a methoxymethyl group, a 1-methoxyethyl group, a 1-ethoxyethyl group, a 1-n-propoxyethyl group, a 1-n-butoxyethyl group, a 1-isobutoxyethyl group, a 1-(2-chloroethoxy)ethyl group, a 1-(2-ethylhexyloxy)ethyl group, a 1-cyclohexyloxyethyl group, and a 1-(2-cyclohexylethoxy)ethyl group, with a 1-ethoxyethyl group and a 1-n-propoxyethyl group preferred. As the acid-decomposable group, a group represented by formula (7) in which one of R⁶ and R⁷ is bonded with R⁸ to form a ring structure can also be suitably used. In this case, R⁶ or R⁷ that is not involved in the formation of the ring structure is preferably a hydrogen atom. The number of ring members in the ring structure is preferably 3 to 10. Examples of such an acid-decomposable group include a 2-tetrahydrofuranyl group and a 2-tetrahydropyranyl group, with a 2-tetrahydrofuranyl group preferred.

The protection reaction of a phenolic hydroxy group can be carried out under known conditions using a general protecting agent. For example, the first resin (A) can be obtained by reacting a base resin (a) of the first resin (A) with a protecting agent without a solvent or in a solvent, such as toluene and hexane, at a reaction temperature of −20 to 50° C. in the presence of an acid or a base.

As the protecting agent, a known protecting agent capable of protecting a phenolic hydroxy group can be used. As the protecting agent, for example, isobutene can be used when the acid-decomposable group is a tert-butyl group, and di-tert-butyl dicarbonate can be used when the acid-decomposable group is a tert-butoxycarbonyl group. When the acid-decomposable group is a silyl group, such as a trimethylsilyl group and a triethylsilyl group, a silicon-containing chloride, such as trimethylsilyl chloride and triethylsilyl chloride, or a silicon-containing triflate compound, such as trimethylsilyl triflate and triethyl triflate can be used. Chloromethyl methyl ether can be used when the acid-decomposable group is a methoxymethyl group, and ethyl vinyl ether for a 1-ethoxyethyl group, n-propyl vinyl ether for a 1-n-propoxyethyl group, 2,3-dihydrofuran for a 2-tetrahydrofuranyl group, and 3,4-dihydro-2H-pyran for a 2-tetrahydropyranyl group can be used.

Examples of the acid include an inorganic acid, such as hydrochloric acid, sulfuric acid, nitric acid, and perchloric acid, and an organic acid, such as methanesulfonic acid, trifluoromethanesulfonic acid, p-toluenesulfonic acid, and benzenesulfonic acid. A salt of the organic acid, such as a pyridinium salt of p-toluenesulfonic acid, can also be used as an acid source. Examples of the base include an inorganic hydroxide, such as sodium hydroxide and potassium hydroxide; an inorganic carbonate, such as sodium carbonate, sodium hydrogen carbonate, potassium carbonate, and cesium carbonate; a metal hydride, such as sodium hydride; and an amine compound, such as pyridine, N,N-dimethyl-4-aminopyridine, imidazole, triethylamine, and diisopropylethylamine.

In another embodiment, the first resin (A) can be obtained by protecting a phenolic hydroxy group of a polymerizable monomer having a phenolic hydroxy group with an acid-decomposable group, and then polymerizing or copolymerizing the polymerizable monomer having a phenolic hydroxy group protected with the acid-decomposable group, and optionally an additional polymerizable monomer. Protecting the phenolic hydroxy group of the polymerizable monomer having a phenolic hydroxy group can be carried out in the same manner as in the protection of the phenolic hydroxy group of the base resin (a).

<Base Resin (a)>

Examples of the base resin (a) of the first resin (A) include a polystyrene resin, an epoxy resin, a polyamide resin, a phenol resin, a polyimide resin, a polyamic acid resin, a polybenzoxazole resin, a polybenzoxazole resin precursor, a silicone resin, a cyclic olefin polymer, a cardo resin, and derivatives thereof, all of which have a plurality of phenolic hydroxy groups. Examples of the derivative of the phenol resin include a polyalkenylphenol resin in which an alkenyl group is bonded to a benzene ring, and examples of the derivative of the polystyrene resin include a hydroxypolystyrene resin derivative in which a phenolic hydroxy group and a hydroxyalkyl group or alkoxy group are bonded to a benzene ring. As the base resin (a), a homopolymer or a copolymer of a polymerizable monomer having a phenolic hydroxy group can also be used. These base resins (a) may be used alone or in combination of two or more. The base resin (a) may have a radical polymerizable functional group. In one embodiment, the base resin (a) has a (meth)acryloyloxy group, an allyl group, or a methallyl group as the radical polymerizable functional group.

<Aqueous Alkaline Solution-Soluble Copolymer (a1) of a Polymerizable Monomer having a Phenolic Hydroxy Group and an Additional Polymerizable Monomer>

In one embodiment, the base resin (a) of the first resin (A) is an aqueous alkaline solution-soluble copolymer (a1) of a polymerizable monomer having a phenolic hydroxy group and an additional polymerizable monomer, and the aqueous alkaline solution-soluble copolymer (a1) has a plurality of phenolic hydroxy groups. In this embodiment, the first resin (A) is one in which at least some of the plurality of phenolic hydroxy groups of the aqueous alkaline solution-soluble copolymer (a1) are protected with an acid-decomposable group. The aqueous alkaline solution-soluble copolymer (a1) may further have an alkali-soluble functional group other than a phenolic hydroxy group, such as a carboxy group, a sulfo group, a phosphoric acid group, an acid anhydride group, or a mercapto group. Examples of the polymerizable functional group of the polymerizable monomer include a radical polymerizable functional group, such as CH₂═CH—, CH₂═C(CH₃)—, CH₂═CHCO—, CH₂═C(CH₃)CO—, and —OC—CH═CH—CO—.

The aqueous alkaline solution-soluble copolymer (a1) can be produced by, for example, the radical polymerization of a polymerizable monomer having a phenolic hydroxy group and an additional polymerizable monomer. After synthesizing the copolymer by radical polymerization, a phenolic hydroxy group may be added to the copolymer. Examples of the polymerizable monomer having a phenolic hydroxy group include 4-hydroxystyrene, 4-hydroxyphenyl (meth)acrylate, 3,5-dimethyl-4-hydroxybenzylacrylamide, 4-hydroxyphenylacrylamide, and 4-hydroxyphenylmaleimide. Examples of the additional polymerizable monomer include polymerizable styrene derivatives, such as styrene, vinyl toluene, α-methylstyrene, p-methylstyrene, and p-ethylstyrene; acrylamide; acrylonitrile; an ether compound of vinyl alcohol, such as vinyl n-butyl ether; a (meth)acrylic acid ester, such as alkyl (meth)acrylates, tetrahydrofurfuryl (meth)acrylate, dimethylaminoethyl (meth)acrylate, diethylaminoethyl (meth)acrylate, glycidyl (meth)acrylate, 2,2,2-trifluoroethyl (meth)acrylate, 2,2,3,3-tetrafluoropropyl (meth)acrylate, and isobornyl (meth)acrylate; an N-substituted maleimide, such as phenylmaleimide, and cyclohexylmaleimide; maleic anhydride; a maleic acid monoester; (meth)acrylic acid, α-bromo(meth)acrylic acid, α-chloro(meth)acrylic acid, β-furyl(meth)acrylic acid, β-styryl(meth)acrylic acid, maleic acid, monomethyl maleate, monoethyl maleate, monoisopropyl maleate, fumaric acid, cinnamic acid, α-cyanocinnamic acid, itaconic acid, crotonic acid, propiolic acid, 3-maleimidopropionic acid, 4-maleimidobutyric acid, and 6-maleimidohexanoic acid. From the viewpoint of heat resistance, the aqueous alkaline solution-soluble copolymer (a1) preferably has one or more cyclic structures, such as an alicyclic structure, an aromatic structure, a polycyclic structure, an inorganic cyclic structure, or a heterocyclic structure.

The polymerizable monomer having a phenolic hydroxy group preferably forms a structural unit represented by formula (1).

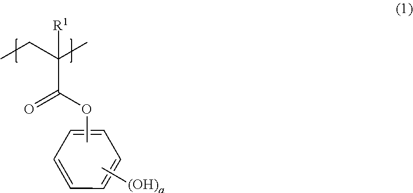

In formula (1), R¹ is a hydrogen atom or an alkyl group having 1 to 5 carbon atoms, and a is an integer from 1 to 5. R¹ is preferably a hydrogen atom or a methyl group. a is preferably an integer from 1 to 3, more preferably 1. 4-Hydroxyphenyl methacrylate is particularly preferable as the polymerizable monomer having a phenolic hydroxy group.

The additional polymerizable monomer preferably forms a structural unit represented by formula (2).

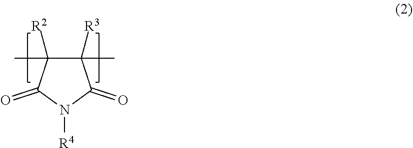

In formula (2), R² and R³ are each independently a hydrogen atom, an alkyl group having 1 to 3 carbon atoms, a fully or partially fluorinated alkyl group having 1 to 3 carbon atoms, or a halogen atom, and R⁴ is a hydrogen atom, a linear alkyl group having 1 to 6 carbon atoms or a cyclic alkyl group having 4 to 12 carbon atoms, a phenyl group, or a phenyl group substituted with at least one selected from the group consisting of a hydroxy group, an alkyl group having 1 to 6 carbon atoms, and an alkoxy group having 1 to 6 carbon atoms. It is preferable that R² and R³ be each independently a hydrogen atom or an alkyl group having 1 to 3 carbon atoms. R⁴ is preferably a cyclic alkyl group having 4 to 12 carbon atoms, a phenyl group, or a phenyl group substituted with at least one selected from the group consisting of a hydroxy group, an alkyl group having 1 to 6 carbon atoms, and an alkoxy group having 1 to 6 carbon atoms, and more preferably a cyclic alkyl group having 4 to 12 carbon atoms or a phenyl group. Among such additional polymerizable monomers, phenylmaleimide and cyclohexylmaleimide are particularly preferable.

In one embodiment, the aqueous alkaline solution-soluble copolymer (a1) has a structural unit represented by formula (1)

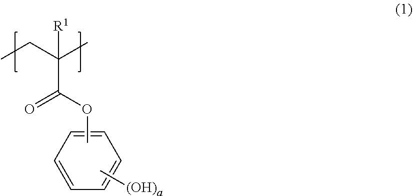

wherein in formula (1), R¹ is a hydrogen atom or an alkyl group having 1 to 5 carbon atoms, a is an integer from 1 to 5, and a structural unit represented by formula (2)

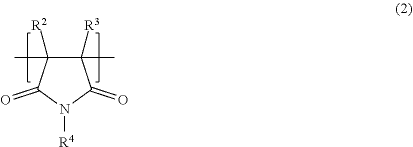

wherein in formula (2), R² and R³ are each independently a hydrogen atom, an alkyl group having 1 to 3 carbon atoms, a fully or partially fluorinated alkyl group having 1 to 3 carbon atoms, or a halogen atom, and R⁴ is a hydrogen atom, a linear alkyl group having 1 to 6 carbon atoms or a cyclic alkyl group having 4 to 12 carbon atoms, a phenyl group, or a phenyl group substituted with at least one selected from the group consisting of a hydroxy group, an alkyl group having 1 to 6 carbon atoms, and an alkoxy group having 1 to 6 carbon atoms.

The use of 4-hydroxyphenyl methacrylate as the polymerizable monomer having a phenolic hydroxy group together with the use of phenylmaleimide or cyclohexylmaleimide as the additional polymerizable monomer is particularly preferable. By using a resin in which these polymerizable monomers are radically polymerized, the shape retainability and developability can be improved and outgassing can be reduced.

A polymerization initiator used when producing the base resin (a) or the aqueous alkaline solution-soluble copolymer (a1) by radical polymerization may be, but not limited to, an azo polymerization initiator, such as 2,2′-azobisisobutyronitrile, 2,2′-azobis(2-methylbutyronitrile), dimethyl 2,2′-azobis(2-methylpropionate), 4,4′-azobis(4-cyanovaleric acid), and 2,2′-azobis(2,4-dimethylvaleronitrile) (AVN); a peroxide polymerization initiator with a 10 hour half-life temperature of 100 to 170° C., such as dicumyl peroxide, 2,5-dimethyl-2,5-di(tert-butylperoxy)hexane, tert-butylcumyl peroxide, di-tert-butyl peroxide, 1,1,3,3-tetramethyl butyl hydroperoxide, and cumene hydroperoxide; or a peroxide polymerization initiator, such as benzoyl peroxide, lauroyl peroxide, 1,1′-di(tert-butylperoxy)cyclohexane, and tert-butyl peroxypivalate. The amount of the polymerization initiator used with respect to 100 parts by mass of the total of the polymerizable monomers is, in general, preferably 0.01 parts by mass or more, 0.05 parts by mass or more, or 0.5 parts by mass or more, and 40 parts by mass or less, 20 parts by mass or less, or 15 parts by mass or less.

A RAFT (Reversible Addition Fragmentation Transfer) agent may be used in combination with the polymerization initiator. The RAFT agent used may be, but is not limited to, a thiocarbonylthio compound, such as a dithioester, a dithiocarbamate, a trithiocarbonate, and a xanthate. With respect to 100 parts by mass of the total of the polymerizable monomers, the RAFT agent may be used in the range of 0.005 to 20 parts by mass, and preferably in the range of 0.01 to 10 parts by mass.

The weight average molecular weight (Mw) of the base resin (a) or the aqueous alkaline solution-soluble copolymer (a1) may be 3,000 to 80,000, preferably 4,000 to 70,000, and more preferably 5,000 to 60,000. The number average molecular weight (Mn) may be 1,000 to 30,000, preferably 1,500 to 25,000, and more preferably 2,000 to 20,000. The polydispersity index (Mw/Mn) may be 1.0 to 3.5, preferably 1.1 to 3.0, and more preferably 1.2 to 2.8. When the weight average molecular weight, the number average molecular weight, and the polydispersity index are within the aforementioned ranges, a positive photosensitive resin composition with excellent alkali solubility and developability can be obtained.

In one embodiment, 10 mol % to 95 mol %, preferably 20 mol % to 80 mol %, and more preferably 25 mol % to 70 mol % of the phenolic hydroxy groups of the first resin (A) are protected with an acid-decomposable group. In the first resin (A), by setting the ratio of the phenolic hydroxy groups protected with the acid-decomposable group to 10 mol % or more, a chemical amplification function can be imparted to the photosensitive resin composition to achieve high sensitivity. By setting the ratio of the phenolic hydroxy groups protected with the acid-decomposable group to 95 mol % or less, the residual amount of the acid-decomposable groups that do not react at the time of exposure can be reduced, and the solubility of exposed parts can be enhanced to achieve high sensitivity. The ratio of the phenolic hydroxy groups protected with the acid-decomposable group is calculated based on the weight reduction ratio (%) of the first resin (A) measured by using a thermogravimetric differential thermal analyzer (TG/DTA). In the present disclosure, when the first resin (A) is a combination of two or more of resins having different protection ratios, the protection ratio of the phenolic hydroxy groups of the first resin (A) is a value when two or more of resins are considered as a single first resin (A) as a whole.

In one embodiment, in the positive photosensitive resin composition, 5 mol % to 65 mol %, preferably 10 mol % to 55 mol %, and more preferably 15 mol % to 50 mol % of the phenolic hydroxy groups of the first resin (A) with respect to the total of the alkali-soluble functional groups of the first resin (A) and the second resin (B) are protected with an acid-decomposable group. By setting the protection ratio of the phenolic hydroxy groups of the first resin (A) with respect to the total of the alkali-soluble functional groups of the first resin (A) and the second resin (B) to 5 mol % or more, a chemical amplification function can be imparted to the photosensitive resin composition to achieve high sensitivity. By setting the protection ratio of the phenolic hydroxy groups of the first resin (A) with respect to the total of the alkali-soluble functional groups of the first resin (A) and the second resin (B) to 65 mol % or less, the solubility of exposed parts can be secured. The alkali-soluble functional groups serving as a basis of the above ratio include a carboxy group, a sulfo group, a phosphoric acid group, an acid anhydride group, a mercapto group, etc., which are optional, as well as a phenolic hydroxy group.

In one embodiment, the first resin (A) is an aqueous alkaline solution-soluble copolymer of a polymerizable monomer having a phenolic hydroxy group and an additional polymerizable monomer, the copolymer having a plurality of phenolic hydroxy groups, at least some of the plurality of phenolic hydroxy groups protected by an acid-decomposable group. In other words, the first resin (A) is one in which an aqueous alkaline solution-soluble copolymer (a1) of a polymerizable monomer having a phenolic hydroxy group and an additional polymerizable monomer is used as the base resin (a), and the aqueous alkaline solution-soluble copolymer (a1) has a plurality of phenolic hydroxy groups, and at least some of these phenolic hydroxy groups are protected with an acid-decomposable group.

In an embodiment in which the aqueous alkaline solution-soluble copolymer (a1) is the base resin (a), it is preferable that the first resin (A) have a structural unit represented by formula (3)

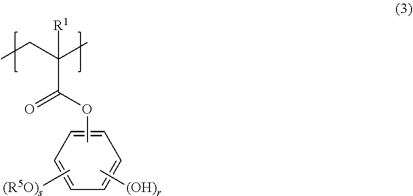

wherein in formula (3), R¹ is a hydrogen atom or an alkyl group having 1 to 5 carbon atoms, R⁵ is an acid-decomposable group, r is an integer from 0 to 5, s is an integer from 0 to 5, provided that r+s is an integer from 1 to 5, and the first resin (A) has at least one of the structural units in which s is an integer of 1 or more. The acid-decomposable group of R⁵ is preferably a group represented by formula (7).

—CR⁶R⁷—O—R⁸ (7)

In formula (7), it is more preferable that R⁶ and R⁷ be each independently a hydrogen atom or a linear or branched alkyl group having 1 to 4 carbon atoms. It is more preferable that R⁸ be a linear, branched or cyclic alkyl group having 1 to 12 carbon atoms, an aralkyl group having 7 to 12 carbon atoms, or an alkenyl group having 2 to 12 carbon atoms, or one of R⁶ and R⁷, and R⁸ be bonded to form a ring structure having 3 to 10 ring members. R⁶, R⁷ and R⁸ may be substituted with a halogen atom selected from the group consisting of fluorine, chlorine, bromine and iodine. Examples of such an acid-decomposable group include a 1-alkoxyalkyl group. Examples of the 1-alkoxyalkyl group include a methoxymethyl group, a 1-methoxyethyl group, a 1-ethoxyethyl group, a 1-n-propoxyethyl group, a 1-n-butoxyethyl group, a 1-isobutoxyethyl group, a 1-(2-chloroethoxy)ethyl group, a 1-(2-ethylhexyloxy)ethyl group, a 1-cyclohexyloxyethyl group, and a 1-(2-cyclohexylethoxy)ethyl group, with a 1-ethoxyethyl group and a 1-n-propoxyethyl group preferred. Examples of the acid-decomposable group in which one of R⁶ and R⁷, and R⁸ are bonded to form a ring structure having 3 to 10 ring members include a 2-tetrahydrofuranyl group and a 2-tetrahydropyranyl group, with a 2-tetrahydrofuranyl group preferred.

In an embodiment in which the aqueous alkaline solution-soluble copolymer (a1) is the base resin (a), it is preferable that the first resin (A) have a structural unit represented by formula (2)

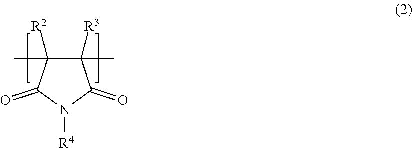

wherein in formula (2), R² and R³ are each independently a hydrogen atom, an alkyl group having 1 to 3 carbon atoms, a fully or partially fluorinated alkyl group having 1 to 3 carbon atoms, or a halogen atom, and R⁴ is a hydrogen atom, a linear alkyl group having 1 to 6 carbon atoms or a cyclic alkyl group having 4 to 12 carbon atoms, a phenyl group, or a phenyl group substituted with at least one selected from the group consisting of a hydroxy group, an alkyl group having 1 to 6 carbon atoms, and an alkoxy group having 1 to 6 carbon atoms. It is preferable that R² and R³ be each independently a hydrogen atom or an alkyl group having 1 to 3 carbon atoms. R⁴ is preferably a cyclic alkyl group having 4 to 12 carbon atoms, a phenyl group, or a phenyl group substituted with at least one selected from the group consisting of a hydroxy group, an alkyl group having 1 to 6 carbon atoms, and an alkoxy group having 1 to 6 carbon atoms.

In one embodiment, the number of structural units represented by formula (3) in which s is an integer of 1 or more, that is, the number of structural units represented by formula (3) in which at least one phenolic hydroxy group is protected with an acid-decomposable group, is 5% to 95%, preferably 15% to 70%, and more preferably 25% to 60% of the total number of structural units of the first resin (A). By setting the ratio of the above structural units to 10% or more, a chemical amplification function can be imparted to the photosensitive resin composition to achieve high sensitivity. By setting the ratio of the above structural units to 95% or less, the residual amount of unreacted acid-decomposable groups can be reduced, and the solubility of exposed parts can be enhanced to achieve high sensitivity.

### Second Resin (B) having an Epoxy Group and a Phenolic Hydroxy Group

The second resin (B) having an epoxy group and a phenolic hydroxy group is an aqueous alkaline solution-soluble resin. The second resin (B) may have an alkali-soluble functional group other than a phenolic hydroxy group. The phenolic hydroxy group and other alkali-soluble functional groups may be protected with an acid-decomposable group. The second resin (B) can be obtained by, for example, reacting some of epoxy groups of a compound having at least two epoxy groups per molecule (hereinafter may be referred to as “epoxy compound”) with the carboxy group of a hydroxybenzoic acid compound. The epoxy groups of the second resin (B) form crosslinking by reacting with a phenolic hydroxy group during heat treatment after development (post-baking), thereby improving the chemical resistance, heat resistance, etc., of a coating. Since a phenolic hydroxy group contributes to solubility in an aqueous alkaline solution during development, the second resin (B) also functions as a dissolution accelerator of the first resin (A) in which the acid-decomposable group is not sufficiently decomposed (deprotected) in exposed parts when exposed at a low exposure dose. On the other hand, since a phenolic hydroxy group is relatively low in alkali solubility as compared with a carboxy group, the second resin (B) is not excessively dissolved in an aqueous alkaline solution in unexposed parts. Therefore, by using the second resin (B), it is possible to make the photosensitive resin composition highly sensitive and to form a pattern with high resolution. In addition, in the second resin (B), since a phenolic hydroxy group having a relatively low acidity as an alkali-soluble functional group coexists with an epoxy group having reactivity with an acid, ring-opening polymerization of an epoxy group of the second resin (B) is less likely to proceed as compared with a resin having a functional group having a high acidity, such as a carboxy group, and an epoxy group. Thus, it is possible to stably maintain the performance of the photosensitive resin composition, such as alkali solubility, crosslinking reactivity, etc., over a long period of time.

When the second resin (B) having both an epoxy group and a phenolic hydroxy group is compared with a blend of a resin having an epoxy group and a resin having a phenolic hydroxy group, the resin having an epoxy group among the components of the blend does not have alkali solubility, so that the alkali solubility of exposed parts may decrease. On the other hand, the second resin (B) is a compound in which all of its components have an alkali-soluble functional group. Therefore, by using the second resin (B), the alkali solubility of the photosensitive resin composition can be easily adjusted, and excellent pattern formability can be imparted to the photosensitive resin composition.

The following reaction formula 1 is an example of the reaction between one epoxy group of an epoxy compound and the carboxy group of a hydroxybenzoic acid compound to form a phenolic hydroxy group-containing compound.

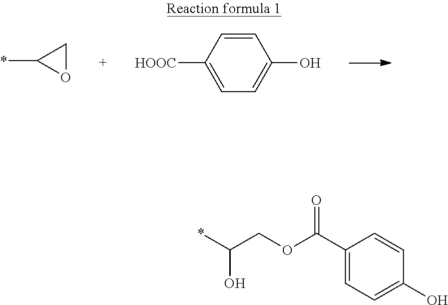

Examples of the compound having at least two epoxy groups per molecule may include a phenol novolak epoxy resin, a cresol novolak epoxy resin, a bisphenol epoxy resin, a biphenol epoxy resin, a naphthalene skeleton-containing epoxy resin, an alicyclic epoxy resin, and a heterocyclic epoxy resin. These epoxy compounds are acceptable provided there are at least two epoxy groups per molecule and may be used alone or in combination of two or more thereof. As these are thermosetting compounds, the structures thereof cannot be unambiguously defined due to differences, such as the presence or absence of epoxy groups, the type of functional groups, and the degree of polymerization, as is common knowledge for a person skilled in the art. One example of the structure of the novolak epoxy resin is illustrated in formula (4). In formula (4), for example, R⁹ is a hydrogen atom, an alkyl group having 1 to 5 carbon atoms, an alkoxy group having 1 to 2 carbon atoms or a hydroxy group, and m is an integer from 1 to 50.

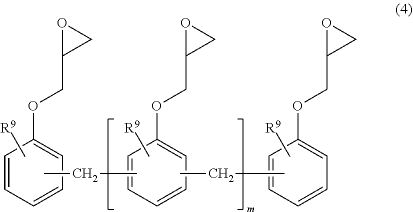

Examples of the phenol novolak epoxy resin include EPICLON® N-770 (DIC Corporation) and jER®-152 (Mitsubishi Chemical Corporation). Examples of the cresol novolak epoxy resin include EPICLON® N-695 (DIC Corporation) and EOCN®-102S (Nippon Kayaku Co., Ltd.). Examples of the bisphenol epoxy resin include a bisphenol-A epoxy resin, such as jER® 828, jER® 1001 (Mitsubishi Chemical Corporation) and YD-128 (trade name, NIPPON STEEL Chemical & Material Co., Ltd.), and a bisphenol-F epoxy resin, such as jER® 806 (Mitsubishi Chemical Corporation) and YDF-170 (trade name, NIPPON STEEL Chemical & Material Co., Ltd.). Examples of the biphenol epoxy resin include jER® YX-4000 and jER® YL-6121H (Mitsubishi Chemical Corporation). Examples of the naphthalene skeleton-containing epoxy resin include NC-7000 (trade name, Nippon Kayaku Co., Ltd.) and EXA-4750 (trade name, DIC Corporation). Examples of the alicyclic epoxy resin include EHPE®-3150 (Daicel Corporation). Examples of the heterocyclic epoxy resin include TEPIC®, TEPIC®-L, TEPIC®-H, and TEPIC®-S (Nissan Chemical Corporation).

The compound having at least two epoxy groups per molecule is preferably a novolak epoxy resin, and more preferably at least one selected from the group consisting of a phenol novolak epoxy resin and a cresol novolak epoxy resin. The positive photosensitive resin composition including the second resin (B) derived from a novolak epoxy resin has excellent pattern formability, and readily adjustable alkali solubility, and exhibits little outgassing.

The hydroxybenzoic acid compound is a compound in which at least one of positions 2 to 6 of benzoic acid has been substituted with a hydroxy group. Examples thereof include salicylic acid, 4-hydroxybenzoic acid, 2,3-dihydroxybenzoic acid, 2,4-dihydroxybenzoic acid, 2,5-dihydroxybenzoic acid, 2,6-dihydroxybenzoic acid, 3,4-dihydroxybenzoic acid, 3,5-dihydroxybenzoic acid, 2-hydroxy-5-nitrobenzoic acid, 3-hydroxy-4-nitrobenzoic acid, and 4-hydroxy-3-nitrobenzoic acid. From the viewpoint of enhancing alkali developability, dihydroxybenzoic acid compounds are preferable. These hydroxybenzoic acid compounds may be used alone or in combination of two or more thereof.

In one embodiment, the second resin (B) is a compound which is a reaction product of the compound having at least two epoxy groups per molecule and the hydroxybenzoic acid compound and has a structure represented by formula (5).

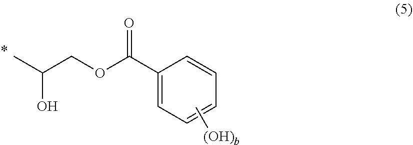

In formula (5), b is an integer from 1 to 5, * represents a bonding site with the residue derived by removing an epoxy group involved in the reaction of the compound having at least two epoxy groups per molecule.

In a method for obtaining the second resin (B) from an epoxy compound and a hydroxybenzoic acid compound, with respect to one equivalent of epoxy groups of the epoxy compound, 0.2 to 0.95 equivalents, preferably 0.3 to 0.9 equivalents, and more preferably 0.4 to 0.8 equivalents of the hydroxybenzoic acid compound may be used. Sufficient alkali solubility can be attained with 0.2 equivalents or more of the hydroxybenzoic acid compound and the increase in molecular weight due to side reactions can be suppressed with 1.0 equivalents or less.

A catalyst may be used to promote the reaction between the epoxy compound and the hydroxybenzoic acid compound. With respect to 100 parts by mass of the mixture of reactants including the epoxy compound and the hydroxybenzoic acid compound, the amount of catalyst used may be 0.1 to 10 parts by mass. The reaction temperature may be 60 to 150° C. and the reaction time may be 3 to 30 hours. Examples of the catalyst for use in this reaction include triethylamine, benzyldimethylamine, triethylammonium chloride, benzyltrimethylammonium bromide, benzyltrimethylammonium iodide, triphenylphosphine, chromium octanoate, and zirconium octanoate.

The second resin (B) has a number average molecular weight (Mn) of preferably 500 to 8,000, more preferably 800 to 6,000, and still more preferably 1,000 to 5,000. When the number average molecular weight is 500 or more, the use of the resin as a photosensitive material is favorable since the alkali solubility is suitable, and when the number average molecular weight is 8,000 or less, the coatability and developability are favorable.

In one embodiment, the epoxy equivalent of the second resin (B) is 300 to 7,000, preferably 400 to 6,000, and more preferably 500 to 5,000. When the epoxy equivalent of the second resin (B) is 300 or more, the second resin (B) can exhibit sufficient alkali solubility. When the epoxy equivalent of the second resin (B) is 7,000 or less, the strength and heat resistance of a coating after curing can be enhanced. The epoxy equivalent is determined by JIS K 7236:2009.

In one embodiment, the hydroxy equivalent of the second resin (B) is 160 to 500, preferably 170 to 400, and more preferably 180 to 300. When the hydroxy equivalent of the second resin (B) is 160 or more, the strength and heat resistance of a coating after curing can be enhanced. When the hydroxy equivalent of the second resin (B) is 500 or less, the second resin (B) can exhibit sufficient alkali solubility. The hydroxy equivalent is determined by JIS K 0070:1992.

In one embodiment, the molar ratio of epoxy group/phenolic hydroxy group of the second resin (B) is 1/18 to 9/2, preferably 2/16 to 8/4, and more preferably 3/14 to 7/6. When the molar ratio of epoxy group/phenolic hydroxy group of the second resin (B) is 1/18 or more, the strength and heat resistance of a coating after curing can be enhanced. When the molar ratio of epoxy group/phenolic hydroxy group of the second resin (B) is 9/2 or less, the second resin (B) can exhibit sufficient alkali solubility. The molar ratio of epoxy group/phenolic hydroxy group is determined based on a theoretical equivalent, which is calculated from the charge ratio of raw materials at the time of producing the second resin (B), for example, the charge ratio of the compound having at least two epoxy groups per molecule and the hydroxybenzoic acid compound.

### [Colorant (C)]

The colorant (C) is at least one selected from the group consisting of a black dye and a black pigment. The black dye and the black pigment can be used in combination. For example, by forming black barrier ribs in an organic EL element using the positive photosensitive resin composition containing the colorant (C), the visibility of a display device, such as an organic EL display, can be improved.

In one embodiment, the colorant (C) includes a black dye. As the black dye, a dye defined by the color index (C.I.) as solvent black 27 to 47 may be used. The black dye is preferably one defined by the C.I. as solvent black 27, 29 or 34. When at least one black dye of the dyes defined by the C.I. as solvent black 27 to 47 is used, the light shielding properties of a coating of the positive photosensitive resin composition after baking can be maintained. The positive photosensitive resin composition containing the black dye, as compared to a positive photosensitive resin composition containing a black pigment, leaves less residue of the colorant (C) during development and can form high definition patterns in a coating.

A black pigment may be used as the colorant (C). Examples of the black pigment include carbon black, carbon nanotubes, acetylene black, graphite, iron black, aniline black, titanium black, a perylene pigment, and a lactam pigment. These black pigments having surface treatment may also be used. Examples of a commercially available perylene pigment include K0084, K0086, and pigment black 21, 30, 31, 32, 33 and 34 manufactured by BASF. Examples of a commercially available lactam pigment include Irgaphor® Black S0100CF manufactured by BASF. The black pigment is preferably at least one selected from the group consisting of carbon black, titanium black, a perylene pigment, and a lactam pigment, due to their high light shielding properties.

In one embodiment, the positive photosensitive resin composition comprises 10 parts by mass to 150 parts by mass, preferably 30 parts by mass to 100 parts by mass, and more preferably 40 parts by mass to 60 parts by mass of the colorant (C), with respect to 100 parts by mass of the total of the first resin (A) and the second resin (B). When the content of the colorant (C) is 10 parts by mass or more with respect to 100 parts by mass of the total described above, the light shielding properties of a coating after baking can be maintained. When the content of the colorant (C) is 150 parts by mass or less with respect to 100 parts by mass of the total described above, a coating can be colored without impairing alkali developability.

### [Photoacid Generator (D)]

The positive photosensitive resin composition includes a photoacid generator (D). The photoacid generator (D) is a compound that generates an acid when exposed to radiation, such as visible light, ultraviolet light, γ rays, and electron beams. The photoacid generator (D) promotes decomposition of the acid-decomposable group of the first resin (A) to regenerate the phenolic hydroxy group, thereby increasing the alkali solubility of the first resin (A). Further, due to the presence of an acid generated from the photoacid generator (D) in parts irradiated with radiation, the resin at these parts is easily dissolved in an aqueous alkaline solution together with the acid. As a result, a pattern with high resolution can be formed with high sensitivity even at a low exposure dose. The photoacid generator (D) may be used alone or in combination of two or more thereof.

The photoacid generator (D) preferably generates an acid having a pKa of 4 or less, and more preferably an acid having a pKa of 3 or less, when irradiated with radiation. Such a photoacid generator (D) can produce an acid having decomposability of the acid-decomposable group.

The photoacid generator (D) preferably generates an acid having a pKa of −15 or more, and more preferably an acid having a pKa of −5 or more, when irradiated with radiation. Such a photoacid generator (D) can maintain the alkali solubility of the second resin (B) during development without excessively advancing the ring-opening polymerization of an epoxy group of the second resin (B) during exposure and heat treatment after exposure (PEB).

Examples of the photoacid generator (D) include trichloromethyl-s-triazine compounds, onium salts, such as sulfonium salts, phosphonium salts, diazonium salts, and iodonium salts, quaternary ammonium salts, diazomethane compounds, imido sulfonate compounds, and oxime sulfonate compounds. Among these, the oxime sulfonate compound is preferably used due to its high sensitivity and high insulating properties.

Examples of the oxime sulfonate compound include a compound represented by formula (6).

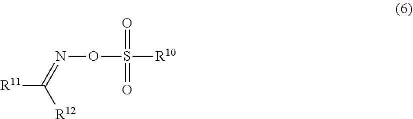

In formula (6), R¹⁰ is a substituted or unsubstituted alkyl group, alkoxy group, or aryl group, or a halogen atom, and R¹¹ and R¹² are each independently a substituted or unsubstituted aryl group, a substituted or unsubstituted heterocyclic group, a cyano group, an acyloxy group, a carboxy group, an alkoxycarbonyl group, or a fluoroalkyl group. R¹¹ and R¹² may be bonded to form a ring structure. The number of ring members in the ring structure is preferably 3 to 10.

Examples of the substituted or unsubstituted alkyl group of R¹⁰ include a linear or branched alkyl group having 1 to 10 carbon atoms, with a methyl group, an ethyl group, and an n-propyl group preferred. Examples of the substituted or unsubstituted alkoxy group of R¹⁰ include a linear or branched alkoxy group having 1 to 5 carbon atoms, with a methoxy group and an ethoxy group preferred. Examples of the substituent of the alkyl group and the alkoxy group of R¹⁰ include a halogen atom (fluorine, chlorine, bromine, and iodine atoms), a cyano group, a nitro group, an aryl group having 6 to 20 carbon atoms, an alkoxy group having 1 to 10 carbon atoms, and a cycloalkyl group having 3 to 10 carbon atoms. The substituted alkyl group of R¹⁰ is preferably a fluoroalkyl group, more preferably a trifluoromethyl group, a pentafluoroethyl group, or a heptafluoropropyl group, and still more preferably a trifluoromethyl group. Examples of the substituted or unsubstituted aryl group of R¹⁰ include an aryl group having 6 to 20 carbon atoms, with a phenyl group, a 4-methylphenyl group, and a naphthyl group preferred. Examples of the substituent of the aryl group of R¹⁰ include an alkyl group having 1 to 5 carbon atoms, an alkoxy group having 1 to 5 carbon atoms, and a halogen atom (fluorine, chlorine, bromine, and iodine atoms). Examples of the halogen atom of R¹⁰ include fluorine, chlorine, bromine and iodine atoms.

Examples of the substituted or unsubstituted aryl groups of R¹¹ and R¹² include an aryl group having 6 to 20 carbon atoms, with a phenyl group and a naphthyl group preferred. Examples of the substituted or unsubstituted heterocyclic groups of R¹¹ and R¹² include a 2-benzofuranyl group, a 3-benzofuranyl group, a 2-benzimidazolyl group, a 2-benzoxazolyl group, a 2-benzothiazolyl group, a 2-indolyl group, a 3-coumarinyl group, a 4-coumarinyl group, a 3-isocoumarinyl group, and a 4-isocoumarinyl group. Examples of the substituents of the aryl groups and the heterocyclic groups of R¹¹ and R¹² include an alkyl group having 1 to 4 carbon atoms, an alkoxy group having 1 to 4 carbon atoms, an acyloxy group having 2 to 4 carbon atoms, and a halogen atom (fluorine, chlorine, bromine, and iodine atoms). Examples of the acyloxy groups of R¹¹ and R¹² include an acetoxy group and a benzoyl group. Examples of the alkoxycarbonyl groups of R¹¹ and R¹² include an ethoxycarbonyl group. Examples of the fluoroalkyl groups of R¹¹ and R¹² include a trifluoromethyl group, a pentafluoroethyl group, and a heptafluoropropyl group. R¹¹ is preferably a cyano group, a carboxy group, an alkoxycarbonyl group, or a fluoroalkyl group, and more preferably a cyano group, or a trifluoromethyl group. R¹² is preferably a substituted or unsubstituted aryl group, or a substituted or unsubstituted heterocyclic group, and preferably a 4-methoxyphenyl group, or a substituted or unsubstituted 2-benzofuranyl group, 3-benzofuranyl group, 3-coumarinyl group, 4-coumarinyl group, 3-isocoumarinyl group, or 4-isocoumarinyl group.

Examples of the oxime sulfonate compound having a ring structure formed by bonding R¹¹ and R¹² together include an oxime sulfonate compound represented by formula (6a).

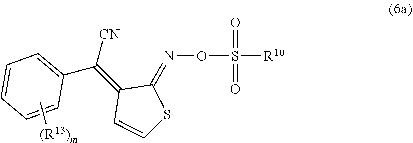

In formula (6a), R¹⁰ is as described in relation to formula (6), R¹³s are each independently an alkyl group, an alkoxy group, or a halogen atom, and m is an integer from 0 to 5.

Examples of the alkyl group of R¹³ include a linear or branched alkyl group having 1 to 10 carbon atoms, with a methyl group, an ethyl group, and an n-propyl group preferred. Examples of the alkoxy group of R¹³ include a linear or branched alkoxy group having 1 to 5 carbon atoms, with a methoxy group and an ethoxy group preferred. Examples of the halogen atom of R¹³ include fluorine, chlorine, bromine and iodine atoms, with chlorine and fluorine atoms preferred. m is preferably 0 or 1.

Examples of the oxime sulfonate compound include (Z,E)-2-(4-methoxyphenyl)([((4-methylphenyl)sulfonyl)oxy]imino)acetonitrile, 2-[2-(propylsulfonyloxyimino)thiophen-3(2H)-ylidene]-2-(2-methylphenyl)acetonitrile, and 2-[2-(4-methylphenylsulfonyloxyimino)thiophen-3(2H)-ylidene]-2-(2-methylphenyl)acetonitrile.

In one embodiment, the positive photosensitive resin composition comprises 0.5 parts by mass to 75 parts by mass, preferably 5 parts by mass to 40 parts by mass, and more preferably 10 parts by mass to 30 parts by mass of the photoacid generator (D), with respect to 100 parts by mass of the total of the first resin (A) and the second resin (B). When the content of the photoacid generator (D) is 0.5 parts by mass or more with respect to 100 parts by mass of the total described above, high sensitivity can be achieved. When the content of the photoacid generator (D) is 75 parts by mass or less with respect to 100 parts by mass of the total described above, the alkali developability is favorable.

### [Dissolution Accelerator (E)]

The positive photosensitive resin composition may further include a dissolution accelerator (E), in order to enhance the solubility of an alkali-soluble part in a developer during development. Examples of the dissolution accelerator (E) include an organic low molecular weight compound selected from the group consisting of a compound having a carboxy group and a compound having a phenolic hydroxy group. The dissolution accelerator (E) may be used alone or in combination of two or more thereof.

In the present disclosure, “low molecular weight compound” refers to a compound having a molecular weight of 1,000 or less. The organic low molecular weight compound described above has a carboxy group or a plurality of phenolic hydroxy groups and is alkali-soluble.

Examples of such an organic low molecular weight compound include aliphatic monocarboxylic acids, such as formic acid, acetic acid, propionic acid, butyric acid, valeric acid, pivalic acid, caproic acid, diethylacetic acid, enanthic acid, and caprylic acid; aliphatic dicarboxylic acids, such as oxalic acid, malonic acid, succinic acid, glutaric acid, adipic acid, pimelic acid, suberic acid, azelaic acid, sebacic acid, brassylic acid, methylmalonic acid, ethylmalonic acid, dimethylmalonic acid, methylsuccinic acid, tetramethylsuccinic acid, and citraconic acid; aliphatic tricarboxylic acids, such as tricarballylic acid, aconitic acid, and camphoronic acid; aromatic monocarboxylic acids, such as benzoic acid, toluic acid, cumic acid, hemimellitic acid, and mesitylenic acid; aromatic polycarboxylic acids, such as phthalic acid, isophthalic acid, terephthalic acid, trimellitic acid, trimesic acid, mellophanic acid, and pyromellitic acid; aromatic hydroxycarboxylic acids, such as dihydroxybenzoic acid, trihydroxybenzoic acid, and gallic acid; other carboxylic acids, such as phenylacetic acid, hydratropic acid, hydrocinnamic acid, mandelic acid, phenylsuccinic acid, atropic acid, cinnamic acid, methyl cinnamate, benzyl cinnamate, cinnamylideneacetic acid, coumaric acid, and umbellic acid; and aromatic polyols, such as catechol, resorcinol, hydroquinone, 1,2,4-benzenetriol, pyrogallol, phloroglucinol, and bisphenol.

The content of the dissolution accelerator (E) in the positive photosensitive resin composition may be 0.1 parts by mass to 50 parts by mass, preferably 1 parts by mass to 35 parts by mass, and more preferably 2 parts by mass to 20 parts by mass, with respect to 100 parts by mass of the total of the first resin (A) and the second resin (B). When the content of the dissolution accelerator (E) is 0.1 parts by mass or more with respect to 100 parts by mass of the total described above, dissolution of the resin components can be effectively promoted, and when the content is 50 parts by mass or less, excessive dissolution of the resin components can be suppressed to enhance the pattern formability, surface quality, etc., of a coating.

### [Optional Component (F)]

The positive photosensitive resin composition may include, as an optional component (F), a resin other than the first resin (A) and the second resin (B), a thermosetting agent, a surfactant, a colorant other than (C), a quinone diazide compound, etc. In the present disclosure, the optional component (F) is defined as any component that does not correspond to any of (A) to (E).

Examples of the resin other than the first resin (A) and the second resin (B) include an acrylic resin, a polystyrene resin, an epoxy resin, a polyamide resin, a phenol resin, a polyimide resin, a polyamic acid resin, a polybenzoxazole resin, a polybenzoxazole resin precursor, a silicone resin, a cyclic olefin polymer, a cardo resin, and derivatives thereof. These resins may or may not have an alkali-soluble functional group.

A thermal radical generator may be used as the thermosetting agent. Examples of a preferred thermal radical generator include organic peroxides, in particular, organic peroxides with a 10 hour half-life temperature of 100 to 170° C., such as dicumyl peroxide, 2,5-dimethyl-2,5-di(tert-butylperoxy)hexane, tert-butylcumyl peroxide, di-tert-butyl peroxide, 1,1,3,3-tetramethylbutyl hydroperoxide, and cumene hydroperoxide.

The content of the thermosetting agent is preferably 5 parts by mass or less, more preferably 4 parts by mass or less, and still more preferably 3 parts by mass or less, with respect to 100 parts by mass of the total of the solid components excluding the thermosetting agent.

The positive photosensitive resin composition may include a surfactant, in order to, for example, improve coatability, smoothness of a coating, or developability of a coating. Examples of the surfactant include: polyoxyethylene alkyl ethers, such as polyoxyethylene lauryl ether, polyoxyethylene stearyl ether, and polyoxyethylene oleyl ether; polyoxyethylene aryl ethers, such as polyoxyethylene octyl phenyl ether, and polyoxyethylene nonyl phenyl ether; nonionic surfactants, such as polyoxyethylene dialkyl esters, including polyoxyethylene dilaurate, and polyoxyethylene distearate; fluorosurfactants, such as Megaface® F-251, Megaface® F-281, Megaface® F-430, Megaface® F-444, Megaface® R-40, Megaface® F-553, Megaface® F-554, Megaface® F-555, Megaface® F-556, Megaface® F-557, Megaface® F-558, Megaface® F-559 (trade names, DIC Corporation), Surflon® S-242, Surflon® S-243, Surflon® S-386, Surflon® S-420, and Surflon® S-611 (trade names, ACG Seimi Chemical Co., Ltd.); and organosiloxane polymers KP323, KP326, and KP341 (trade names, Shin-Etsu Chemical Co., Ltd.). The surfactant may be used alone or in combination of two or more.

The content of the surfactant is preferably 2 parts by mass or less, more preferably 1 parts by mass or less, and still more preferably 0.5 parts by mass or less, with respect to 100 parts by mass of the total of the solid components excluding the surfactant.

The positive photosensitive resin composition may include a second colorant other than the colorant (C). Examples of the second colorant include a dye, an organic pigment, and an inorganic pigment, and the second colorant may be used according to the intended purpose. The second colorant may be used in an amount that does not impair the effect of the invention.

Examples of the dye include an azo dye, a benzoquinone dye, a naphthoquinone dye, an anthraquinone dye, a cyanine dye, a squarylium dye, a croconium dye, a merocyanine dye, a stilbene dye, a diphenylmethane dye, a triphenylmethane dye, a fluoran dye, a spiropyran dye, a phthalocyanine dye, an indigo dye, a fulgide dye, a nickel complex dye, and an azulene dye.

Examples of the pigment include C.I. pigment yellow 20, 24, 86, 93, 109, 110, 117, 125, 137, 138, 147, 148, 153, 154, and 166; C.I. pigment orange 36, 43, 51, 55, 59, and 61; C.I. pigment red 9, 97, 122, 123, 149, 168, 177, 180, 192, 215, 216, 217, 220, 223, 224, 226, 227, 228, and 240; C.I. pigment violet 19, 23, 29, 30, 37, 40, and 50; C.I. pigment blue 15, 15:1, 15:4, 22, 60, and 64; C.I. pigment green 7; and C.I. pigment brown 23, 25, and 26.

The photoacid generator (D) described above and the quinone diazide compound may be used in combination. Examples of the quinone diazide compound include a polyhydroxy compound to which a sulfonic acid of a quinone diazide is bonded via an ester, a polyamino compound to which a sulfonic acid of a quinone diazide is bonded via a sulfonamide, and a polyhydroxy polyamino compound to which a sulfonic acid of a quinone diazide is bonded via an ester or sulfonamide. From the viewpoint of contrast between exposed and unexposed parts, it is preferable that at least 20 mol % of the total of the functional groups of the polyhydroxy compound or polyamino compound be substituted with a quinone diazide.

Examples of the polyhydroxy compound include Bis-Z, BisP-EZ, TekP-4HBPA, TrisP-HAP, TrisP-PA, TrisP-SA, TrisOCR-PA, BisOCHP-Z, BisP-MZ, BisP-PZ, BisP-IPZ, BisOCP-IPZ, BisP-CP, BisRS-2P, BisRS-3P, BisP-OCHP, methylenetris-FR-CR, BisRS-26X, DML-MBPC, DML-MBOC, DML-OCHP, DML-PCHP, DML-PC, DML-PTBP, DML-34X, DML-EP, DML-POP, dimethylol-BisOC-P, DML-PFP, DML-PSBP, DML-MTrisPC, TriML-P, TriML-35XL, TML-BP, TML-HQ, TML-pp-BPF, TML-BPA, TMOM-BP, HML-TPPHBA, and HML-TPHAP (trade names, Honshu Chemical Industry Co., Ltd.), BIR-OC, BIP-PC, BIR-PC, BIR-PTBP, BIR-PCHP, BIP-BIOC-F, 4PC, BIR-BIPC-F, TEP-BIP-A, 46DMOC, 46DMOEP, and TM-BIP-A (trade names, Asahi Yukizai Corporation), 2,6-dimethoxymethyl-4-tert-butylphenol, 2,6-dimethoxymethyl-p-cresol, 2,6-diacetoxymethyl-p-cresol, naphthol, tetrahydroxybenzophenone, gallic acid methyl ester, bisphenol A, bisphenol E, methylene bisphenol, and BisP-AP (trade name, Honshu Chemical Industry Co., Ltd.), but are not limited thereto.

Examples of the polyamino compound include 1,4-phenylenediamine, 1,3-phenylenediamine, 4,4′-diaminodiphenyl ether, 4,4′-diaminodiphenylmethane, 4,4′-diaminodiphenyl sulfone, and 4,4′-diaminodiphenyl sulfide, but are not limited thereto.

Examples of the polyhydroxy polyamino compound include 2,2-bis(3-amino-4-hydroxyphenyl)hexafluoropropane, and 3,3′-dihydroxybenzidine, but are not limited thereto.

The quinone diazide compound is preferably a 1,2-naphthoquinonediazido-4-sulfonic acid ester or a 1,2-naphthoquinonediazido-5-sulfonic acid ester of the polyhydroxy compound.

The quinone diazide compound forms a carboxy group when exposed to ultraviolet light, etc., through the reaction illustrated in reaction formula 2 below. The formation of the carboxy group makes an exposed part (coating) soluble in an aqueous alkaline solution and generates alkali developability in the part.

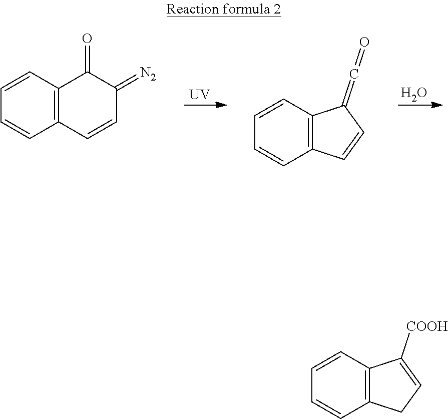

In one embodiment, the positive photosensitive resin composition comprises 0.5 parts by mass to 75 parts by mass, preferably 2 parts by mass to 40 parts by mass, and more preferably 5 parts by mass to 30 parts by mass of the quinone diazide compound, with respect to 100 parts by mass of the total of the first resin (A) and the second resin (B). When the content of the quinone diazide compound is 0.5 parts by mass or more with respect to 100 parts by mass of the total described above, high sensitivity can be achieved. When the content of the quinone diazide compound is 75 parts by mass or less with respect to 100 parts by mass of the total described above, the alkali developability is favorable.

### [Solvent (G)]

The positive photosensitive resin composition may be dissolved in a solvent (G) and used as a solution (note that when a black pigment is included, the pigment is in suspension). For example, by mixing specific amounts of the colorant (C), and the photoacid generator (D), and optionally the dissolution accelerator (E), and the optional component (F), such as a thermosetting agent and a surfactant, with a solution obtained by dissolving the first resin (A) and the second resin (B) in the solvent (G), the photosensitive resin composition may be prepared in solution. The positive photosensitive resin composition may be adjusted to have a viscosity suitable for the coating method used by changing the amount of solvent (G).

Examples of the solvent (G) include: glycol ethers, such as ethylene glycol monomethyl ether, ethylene glycol dimethyl ether, ethylene glycol methyl ethyl ether, and ethylene glycol monoethyl ether; ethylene glycol alkyl ether acetates, such as methyl cellosolve acetate, and ethyl cellosolve acetate; diethylene glycol compounds, such as diethylene glycol monomethyl ether, diethylene glycol diethyl ether, diethylene glycol dimethyl ether, diethylene glycol ethyl methyl ether, diethylene glycol monoethyl ether, and diethylene glycol monobutyl ether; propylene glycol alkyl ether acetate compounds, such as propylene glycol methyl ether acetate and propylene glycol ethyl ether acetate; aromatic hydrocarbons, such as toluene and xylene; ketones, such as methyl ethyl ketone, methyl amyl ketone, cyclohexanone, 4-hydroxy-4-methyl-2-pentanone, and cyclohexanone; esters, such as ethyl 2-hydroxypropionate, methyl 2-hydroxy-2-methylpropionate, ethyl 2-hydroxy-2-methylpropionate, ethyl ethoxyacetate, ethyl hydroxyacetate, methyl 2-hydroxy-2-methylbutanoate, methyl 3-methoxypropionate, ethyl 3-methoxypropionate, methyl 3-ethoxypropionate, ethyl 3-ethoxypropionate, ethyl acetate, butyl acetate, methyl lactate, ethyl lactate, and γ-butyrolactone; and amide compounds, such as N-methyl-2-pyrrolidone, N,N-dimethylformamide, and N,N-dimethylacetamide. The solvent may be used alone or in combination of two or more thereof.

The positive photosensitive resin composition may be prepared by dissolving or dispersing the first resin (A), the second resin (B), the colorant (C), and the photoacid generator (D), and if necessary, the dissolution accelerator (E) or the optional component (F), in the solvent (G) and mixing them. Depending on the intended use, the solid concentration of the positive photosensitive resin composition may be suitably determined. For example, the solid concentration of the positive photosensitive resin composition may be 1 to 60% by mass, 3 to 50% by mass, or 5 to 40% by mass.

A publicly-known method may be used for a dispersion mixing method when a pigment is used. For example, a ball type mixer, such as a ball mill, a sand mill, a bead mill, a paint shaker, and a rocking mill, a blade type mixer, such as a kneader, a paddle mixer, a planetary mixer, and a Henschel mixer, and a roll type mixer, such as a three-roll mixer, may be used, as well as a mortar machine, a colloid mill, ultrasonic waves, a homogenizer, and a rotation and revolution mixer. From the viewpoint of dispersion efficiency and fine dispersing, a bead mill is preferably used.

The prepared positive photosensitive resin composition is usually filtered prior to use. Examples of the filtration means include a millipore filter having a pore diameter of 0.05 to 1.0 μm.

The positive photosensitive resin composition thus prepared is excellent in long term storage stability.

### [Method of Using Positive Photosensitive Resin Composition]

When the positive photosensitive resin composition is used in radiation lithography, the positive photosensitive resin composition is first dissolved or dispersed in a solvent to prepare a coating composition. Next, the coating composition may be applied to the surface of a substrate, and the solvent may be removed by means of heating, etc., to form a coating. There is no particular limitation on the method for applying the coating composition on the surface of the substrate, and for example, a spray method, a roll coating method, a slit method, or a spin coating method may be used.

After applying the coating composition to the surface of the substrate, the solvent is typically removed by heating to form a coating (pre-baking). Although the heating conditions vary depending on the type of each component, the blending ratio, etc., the coating can be usually obtained by heat treatment at 70 to 130° C., for example, for 30 seconds to 20 minutes on a hot plate, or for 1 to 60 minutes in an oven.

Next, the prebaked coating is irradiated with radiation (e.g., visible light, ultraviolet, far-ultraviolet, X-rays, electron beams, gamma rays, synchrotron radiation, etc.) through a photomask having a predetermined pattern (exposure step). When the oxime sulfonate compound is used as the photoacid generator (D), preferable radiation is ultraviolet to visible light having a wavelength of 250 to 450 nm. In one embodiment, the radiation is i-rays. In another embodiment, the radiation is g-, h- and i-rays.

After the exposure step, a heat treatment (PEB) for promoting the decomposition of the acid-decomposable group by an acid generated from the photoacid generator (D) can be carried out. The alkali solubility of the first resin (A) of exposed parts can be enhanced by PEB. Although the heating conditions vary depending on the type of each component, the blending ratio, etc., PEB can be usually carried out by heat treatment at 70 to 140° C., for example, for 30 seconds to 20 minutes on a hot plate, or for 1 to 60 minutes in an oven.

After the PEB step, the coating is developed by bringing the coating into contact with a developer, and unnecessary parts are removed to form a pattern in the coating (developing step). The developer used may be an aqueous solution of an alkali compound, for example: inorganic alkalis, such as sodium hydroxide, potassium hydroxide, sodium carbonate, sodium silicate, sodium metasilicate, and ammonia water; primary amines, such as ethylamine and n-propylamine; secondary amines, such as diethylamine and di-n-propylamine; tertiary amines, such as triethylamine and methyldiethylamine; alcohol amines, such as dimethylethanolamine and triethanolamine; quaternary ammonium salts, such as tetramethylammonium hydroxide, tetraethylammonium hydroxide, and choline; and cyclic amines, such as pyrrole, piperidine, 1,8-diazabicyclo[5.4.0]-7-undecene, and 1,5-diazabicyclo[4.3.0]-5-nonane. An aqueous solution obtained by adding a water-soluble organic solvent, such as methanol and ethanol, a surfactant, etc., to an aqueous alkali solution in appropriate amounts may be used as the developer. The developing time is typically between 30 and 180 seconds. The developing method may be any of a liquid filling method, a shower method, and a dipping method. After the development, a pattern can be formed in the coating by cleaning with running water for 30 to 90 seconds to remove unnecessary parts, and air-drying with compressed air or compressed nitrogen.

Then, a cured coating can be obtained by subjecting the patterned coating to heat treatment using a heating device, such as a hot plate or an oven, for example, at 100 to 350° C. for 20 to 200 minutes (post-baking, heat treatment step). During the heat treatment, the temperature may be maintained constant, continuously increased, or increased in a stepwise manner. The heat treatment is preferably carried out under a nitrogen atmosphere.

The optical density (OD value) of a cured coating of the positive photosensitive resin composition is preferably 0.5 or more, more preferably 0.7 or more, and still more preferably 1.0 or more, per μm of coating thickness. When the OD value of a cured coating is 0.5 or more per μm of coating thickness, sufficient light shielding properties can be achieved.

A method for producing an organic EL element barrier rib or insulating film according to one embodiment comprises: preparing a coating composition by dissolving or dispersing a positive photosensitive resin composition in a solvent; applying the coating composition to a substrate to form a coating; drying the coating by removing the solvent contained in the coating; irradiating the dried coating with radiation through a photomask thereby exposing the coating; heating the exposed coating to decompose at least some of the acid-decomposable groups of the first resin (A); developing the exposed and then heated coating by bringing the coating into contact with a developer to form a pattern in the coating; and heat treating the patterned coating at a temperature of 100° C. to 350° C. to form the organic EL element barrier rib or insulating film.

In the positive photosensitive resin composition according to one embodiment, the epoxy equivalent of the second resin (B) having an epoxy group and a phenolic hydroxy group is 300 to 1,800, and the photoacid generator (D) generates trifluoromethanesulfonic acid. When the epoxy equivalent of the second resin (B) is 300 or more and 1,800 or less, heat sagging of a coating at the time of heat treatment can be suppressed. The epoxy equivalent of the second resin (B) having an epoxy group and a phenolic hydroxy group is preferably 400 or more, more preferably 500 or more, and still more preferably 600 or more. The epoxy equivalent of the second resin (B) having an epoxy group and a phenolic hydroxy group is preferably 1,500 or less, more preferably 1,000 or less, and still more preferably 900 or less. As the photoacid generator (D), by using one which generates trifluoromethanesulfonic acid (pKa=−13), which is a superacid, the pattern formability can be enhanced. The positive photosensitive resin composition according to this embodiment is suitable for forming a thick film because of its particularly high sensitivity, and a coating can be cured in a state in which the pattern shape of the coating is retained with high accuracy even when the coating is exposed to a high temperature during post-baking. Therefore, the positive photosensitive resin composition according to this embodiment can be suitably used in a halftone exposure process.

In this embodiment, the number average molecular weight (Mn) of the second resin (B) having an epoxy group and a phenolic hydroxy group is preferably 500 to 8,000, more preferably 800 to 6,000, and still more preferably 1,000 to 5,000. When the number average molecular weight is 500 or more, the use of the resin as a photosensitive material is favorable since the alkali solubility is suitable, and when the number average molecular weight is 8,000 or less, the coatability and developability are favorable.

In this embodiment, the photoacid generator (D) is preferably PAG-169 (manufactured by BASF).

In this embodiment, the first resin (A) is preferably a copolymer containing a structural unit represented by formula (3) and a structural unit represented by formula (2). The structural unit represented by formula (3) and the structural unit represented by formula (2) are as described above.

In this embodiment, the acid-decomposable group of the first resin (A) is preferably a group represented by formula (7), more preferably a 1-alkoxyalkyl group, or a group represented by formula (7) in which one of R⁶ and R⁷ is bonded with R⁸ to form a ring structure, and still more preferably a 1-ethoxyethyl group, a 1-n-propoxyethyl group, a 2-tetrahydrofuranyl group, or a 2-tetrahydropyranyl group. R⁶, R⁷ and R⁸ of the group represented by formula (7) are as described above.

In the positive photosensitive resin composition according to this embodiment, the content of the colorant (C) is preferably 10 parts by mass to 150 parts by mass, more preferably 30 parts by mass to 100 parts by mass, and still more preferably 40 parts by mass to 90 parts by mass, with respect to 100 parts by mass of the total of the first resin (A) and the second resin (B). When the content of the colorant (C) is 40 parts by mass or more with respect to 100 parts by mass of the total of the first resin (A) and the second resin (B), the light shielding properties when a coating is a thick film and the pattern formability of a coating are favorable, and when the content is 150 parts by mass or less, a coating can be colored without impairing alkali developability.

One embodiment is an organic EL element barrier rib comprising a cured product of the positive photosensitive resin composition.

One embodiment is an organic EL element insulating film comprising a cured product of the positive photosensitive resin composition.

One embodiment is an organic EL element comprising a cured product of the positive photosensitive resin composition.

### EXAMPLES

Hereinafter, the present invention will be specifically described based on Examples and Comparative Examples, but the present invention is not limited to the Examples.

### (1) Raw Materials

The raw materials used in Examples and Comparative Examples were prepared or obtained as follows.

The weight average molecular weights and the number average molecular weights of the first resin (A), the second resin (B), and other resins were calculated using a calibration curve prepared using a standard substance of polystyrene under the following measurement conditions.
Apparatus name: Shodex® GPC-101
Column: Shodex® LF-804
Mobile phase: tetrahydrofuran
Flow rate: 1.0 mL/min
Detector: Shodex® RI-71
Temperature: 40° C.

### Reference Production Example 1

### Production of an Aqueous Alkaline Solution-Soluble Copolymer of a Polymerizable Monomer having a Phenolic Hydroxy Group and an Additional Polymerizable Monomer (PCX-02e)

25.5 g of 4-hydroxyphenyl methacrylate (“PQMA” manufactured by Showa Denko K.K.) and 4.50 g of N-cyclohexylmaleimide (manufactured by Nippon Shokubai Co., Ltd.) were completely dissolved in 77.1 g of 1-methoxy-2-propyl acetate (manufactured by Daicel Corporation) as a solvent, and 3.66 g of V-601 (manufactured by Fujifilm Wako Pure Chemical Corporation) as a polymerization initiator was completely dissolved in 14.6 g of 1-methoxy-2-propyl acetate (manufactured by Daicel Corporation), respectively. The obtained two solutions were simultaneously added dropwise for 2 hours to 61.2 g of 1-methoxy-2-propyl acetate (Daicel Corporation) heated to 85° C. under a nitrogen atmosphere in a 300 mL 3-neck flask, and then reacted for 3 hours at 85° C. The reaction solution cooled to room temperature was added dropwise to 815 g of toluene to precipitate a copolymer. The precipitated copolymer was collected by filtration, and dried under vacuum at 90° C. for 4 hours to collect 32.4 g of white powder. The obtained PCX-02e had a number average molecular weight of 3,100 and a weight average molecular weight of 6,600.

### Reference Production Example 2

### Production of a Copolymer of Glycidyl Methacrylate and Methacrylic Acid (GMA-MAA)

99.5 g (0.7 mol) of glycidyl methacrylate (GMA), and 8.6 g (0.1 mol) of methacrylic acid (MAA) were completely dissolved in 72.1 g of propylene glycol monomethyl ether (PGME), and 7.6 g of V-65 (manufactured by Fujifilm Wako Pure Chemical Corporation) as a polymerization initiator was completely dissolved in 7.6 g of PGME, respectively. The obtained two solutions were simultaneously added dropwise for 2 hours to 172.6 g of PGME heated to 80° C. under a nitrogen atmosphere in a 500 mL 3-neck flask, and then stirred for 2 hours for the reaction. Thus, a copolymer of glycidyl methacrylate and methacrylic acid (GMA-MAA) having a molar ratio of glycidyl methacrylate to methacrylic acid of 7:1 was obtained in the form of a PGMEA solution having a solid content of 30% by mass. Since the obtained GMA-MAA has a carboxy group and an epoxy group in its molecule, it has high self-reactivity, that is, a ring-opening polymerization of an epoxy group easily proceeds. Therefore, when GMA-MAA was reprecipitated and dried under vacuum, its molecular weight increased to prevent isolation. A PGMEA solution of GMA-MAA was less stable, and the increase in its molecular weight proceeded over time to increase the viscosity of the solution.

### First Resin (A)

### Production Example 1

### Production of a First Resin (A) in which a Phenolic Hydroxy Group is Protected with a 1-ethoxyethyl Group (PCX-02e-EOE)

In a 100 mL 3-neck flask, 10.0 g of an aqueous alkaline solution-soluble copolymer of a polymerizable monomer having a phenolic hydroxy group and an additional polymerizable monomer (PCX-02e), and 0.60 g of a pyridinium salt of p-toluenesulfonic acid (manufactured by Tokyo Chemical Industry Co., Ltd.) as an acid catalyst were dissolved in 50.0 g of tetrahydrofuran (manufactured by Fujifilm Wako Pure Chemical Corporation). Thereafter, the mixture was ice-cooled under a nitrogen gas atmosphere, and 6.88 g of ethyl vinyl ether (manufactured by Tokyo Chemical Industry Co., Ltd.) was added dropwise over 1 hour. The mixture was then stirred at room temperature for 16 hours. After neutralizing the acid catalyst with a saturated aqueous sodium hydrogen carbonate solution, the aqueous layer was removed.

The organic layer was further washed twice with water. Thereafter, tetrahydrofuran was distilled off. The obtained solid was dissolved in 50.0 g of ethyl acetate and added dropwise in 200 g of toluene to precipitate the product. The precipitate was collected by filtration and dried under vacuum at 80° C. for 4 hours to collect 11.0 g of white powder. The obtained powder was dissolved in propylene glycol monomethyl acetate to obtain a solution having a solid content of 20% by mass of a first resin (A) (PCX-02e-EOE) in which a phenolic hydroxy group was protected with a 1-ethoxyethyl group. The obtained PCX-02e-EOE had a number average molecular weight of 4,300, a weight average molecular weight of 7,900, a ratio of phenolic hydroxy groups protected with an acid-decomposable group of 65 mol %, and a number of structural units represented by formula (3) in which at least one phenolic hydroxy group was protected with an acid-decomposable group of 55% of the total number of structural units of the first resin (A). The ratio of phenolic hydroxy groups protected with an acid-decomposable group was calculated from a weight reduction rate (%) of the first resin (A) at 260° C., when the temperature was raised from room temperature to 250° C. at a rate of temperature rise of 10° C./min, held for 10 minutes, and further raised to 400° C. at a rate of temperature rise of 10° C./min in a nitrogen gas stream, using a thermogravimetric differential thermal analyzer (TG/DTA6200, manufactured by Hitachi High-Tech Science Corporation).

### Production Example 2

### Production of a First Resin (A) in which a Phenolic Hydroxy Group is Protected with a Tert-butoxycarbonyl Group (PCX-02e-Boc)

In a 100 mL 3-neck flask, 10.0 g of an aqueous alkaline solution-soluble copolymer of a polymerizable monomer having a phenolic hydroxy group and an additional polymerizable monomer (PCX-02e), and 1.74 g of triethylamine (manufactured by Fujifilm Wako Pure Chemical Corporation) as a base were dissolved in 50.0 g of tetrahydrofuran (manufactured by Fujifilm Wako Pure Chemical Corporation). Thereafter, the mixture was ice-cooled under a nitrogen gas atmosphere, and 3.47 g of di-tert-butyl dicarbonate (manufactured by Tokyo Chemical Industry Co., Ltd.) was added dropwise over 1 hour. The mixture was then stirred at room temperature for 16 hours. Thereafter, tetrahydrofuran was distilled off, and the obtained solid was dissolved in 50.0 g of ethyl acetate and added dropwise in 200 g of hexane to precipitate the product. The precipitate was collected by filtration and dried under vacuum at 80° C. for 4 hours to collect 10.3 g of white powder. The obtained powder was dissolved in propylene glycol monomethyl acetate to obtain a solution having a solid content of 20% by mass of a first resin (A) (PCX-02e-Boc) in which a phenolic hydroxy group was protected with a tert-butoxycarbonyl group. The obtained PCX-02e-Boc had a number average molecular weight of 4,400, a weight average molecular weight of 7,800, a ratio of phenolic hydroxy groups protected with an acid-decomposable group of 30 mol %, and a number of structural units represented by formula (3) in which at least one phenolic hydroxy group was protected with an acid-decomposable group of 26% of the total number of structural units of the first resin (A). The ratio of phenolic hydroxy groups protected with an acid-decomposable group was calculated from a weight reduction rate (%) of the first resin (A) at 220° C., when the temperature was raised from room temperature to 400° C. at a rate of temperature rise of 10° C./min in a nitrogen gas stream, using a thermogravimetric differential thermal analyzer (TG/DTA6200, manufactured by Hitachi High-Tech Science Corporation).

### Production Example 3

### Production of a First Resin (A) in which a Phenolic Hydroxy Group is Protected with a 2-tetrahydrofuranyl Group (PCX-02e-THF)

In a 100 mL 3-neck flask, 10.0 g of an aqueous alkaline solution-soluble copolymer of a polymerizable monomer having a phenolic hydroxy group and an additional polymerizable monomer (PCX-02e), and 0.60 g of a pyridinium salt of p-toluenesulfonic acid (manufactured by Tokyo Chemical Industry Co., Ltd.) as an acid catalyst were dissolved in 50.0 g of tetrahydrofuran (manufactured by Fujifilm Wako Pure Chemical Corporation). Thereafter, the mixture was ice-cooled under a nitrogen gas atmosphere, and 6.69 g of 2,3-dihydrofuran (manufactured by Tokyo Chemical Industry Co., Ltd.) was added dropwise over 1 hour. The mixture was then stirred at room temperature for 16 hours. After neutralizing the acid catalyst with a saturated aqueous sodium hydrogen carbonate solution, the aqueous layer was removed. The organic layer was further washed twice with water. Thereafter, tetrahydrofuran was distilled off. The obtained solid was dissolved in 50.0 g of ethyl acetate and added dropwise in 200 g of toluene to precipitate the product. The precipitate was collected by filtration and dried under vacuum at 80° C. for 4 hours to collect 11.0 g of white powder. The obtained powder was dissolved in propylene glycol monomethyl acetate to obtain a solution having a solid content of 20% by mass of a first resin (A) (PCX-02e-THF) in which a phenolic hydroxy group was protected with a 2-tetrahydrofuranyl group. The obtained PCX-02e-THF had a number average molecular weight of 3,716, a weight average molecular weight of 6,806, a ratio of phenolic hydroxy groups protected with an acid-decomposable group of 65 mol %, and a number of structural units represented by formula (3) in which at least one phenolic hydroxy group was protected with an acid-decomposable group of 55% of the total number of structural units of the first resin (A). The ratio of phenolic hydroxy groups protected with an acid-decomposable group was calculated from a weight reduction rate (%) of the first resin (A) at 260° C., when the temperature was raised from room temperature to 250° C. at a rate of temperature rise of 10° C./min, held for 10 minutes, and further raised to 400° C. at a rate of temperature rise of 10° C./min in a nitrogen gas stream, using a thermogravimetric differential thermal analyzer (TG/DTA6200, manufactured by Hitachi High-Tech Science Corporation).

### Production Example 4

### Production of a First Resin (A) in which a Phenolic Hydroxy Group is Protected with a 1-n-propoxyethyl Group (PCX-02e-POE)

In a 100 mL 3-neck flask, 10.0 g of an aqueous alkaline solution-soluble copolymer of a polymerizable monomer having a phenolic hydroxy group and an additional polymerizable monomer (PCX-02e), and 0.60 g of a pyridinium salt of p-toluenesulfonic acid (manufactured by Tokyo Chemical Industry Co., Ltd.) as an acid catalyst were dissolved in 50.0 g of tetrahydrofuran (manufactured by Fujifilm Wako Pure Chemical Corporation). Thereafter, the mixture was ice-cooled under a nitrogen gas atmosphere, and 8.23 g of n-propyl vinyl ether (manufactured by Tokyo Chemical Industry Co., Ltd.) was added dropwise over 1 hour. The mixture was then stirred at room temperature for 16 hours. After neutralizing the acid catalyst with a saturated aqueous sodium hydrogen carbonate solution, the aqueous layer was removed. The organic layer was further washed twice with water. Thereafter, tetrahydrofuran was distilled off. The obtained solid was dissolved in 50.0 g of ethyl acetate and added dropwise in 200 g of toluene to precipitate the product. The precipitate was collected by filtration and dried under vacuum at 80° C. for 4 hours to collect 11.0 g of white powder. The obtained powder was dissolved in propylene glycol monomethyl acetate to obtain a solution having a solid content of 20% by mass of a first resin (A) (PCX-02e-POE) in which a phenolic hydroxy group was protected with a 1-n-propoxyethyl group. The obtained PCX-02e-POE had a number average molecular weight of 4,550, a weight average molecular weight of 8,054, a ratio of phenolic hydroxy groups protected with an acid-decomposable group of 65 mol %, and a number of structural units represented by formula (3) in which at least one phenolic hydroxy group was protected with an acid-decomposable group of 55% of the total number of structural units of the first resin (A). The ratio of phenolic hydroxy groups protected with an acid-decomposable group was calculated from a weight reduction rate (%) of the first resin (A) at 260° C., when the temperature was raised from room temperature to 250° C. at a rate of temperature rise of 10° C./min, held for 10 minutes, and further raised to 400° C. at a rate of temperature rise of 10° C./min in a nitrogen gas stream, using a thermogravimetric differential thermal analyzer (TG/DTA6200, manufactured by Hitachi High-Tech Science Corporation).

### Second Resin (B)

### Production Example 5

### Production of a Second Resin having an Epoxy Group and a Phenolic Hydroxy Group (N770OH70)

In a 300 mL 3-neck flask, 75.2 g of γ-butyrolactone (manufactured by Mitsubishi Chemical Corporation) as a solvent, and 37.6 g of EPICLON® N-770 (phenol novolak epoxy resin, manufactured by DIC Corporation, epoxy equivalent: 188) as a compound having at least two epoxy groups per molecule were added, and dissolved under a nitrogen gas atmosphere at 60° C. 20.1 g (0.65 equivalents based on 1 equivalent of epoxy) of 3,5-dihydroxybenzoic acid (manufactured by Fujifilm Wako Pure Chemical Corporation) as a hydroxybenzoic acid compound, and 0.173 g (0.660 mmol) of triphenylphosphine (manufactured by Tokyo Chemical Industry Co., Ltd.) as a reaction catalyst were added thereto and reacted at 110° C. for 24 hours. The reaction solution was returned to room temperature and diluted with γ-butyrolactone to a solid content of 20% by mass, and the solution was filtered to obtain 286.5 g of a solution of a second resin having an epoxy group and a phenolic hydroxy group (N770OH70). The obtained reaction product had a number average molecular weight of 2,400, a weight average molecular weight of 8,300, and an epoxy equivalent of 2,000.

### Production Example 6

### Production of a Second Resin having an Epoxy Group and a Phenolic Hydroxy Group (N695OH70)

In a 300 mL 3-neck flask, 75.2 g of γ-butyrolactone (manufactured by Mitsubishi Chemical Corporation) as a solvent, and 37.8 g of EPICLON® N-695 (cresol novolak epoxy resin, manufactured by DIC Corporation, epoxy equivalent: 214) as a compound having at least two epoxy groups per molecule were added, and dissolved under a nitrogen gas atmosphere at 60° C. 20.1 g (0.65 equivalents based on 1 equivalent of epoxy) of 3,5-dihydroxybenzoic acid (manufactured by Fujifilm Wako Pure Chemical Corporation) as a hydroxybenzoic acid compound, and 0.166 g (0.660 mmol) of triphenylphosphine (manufactured by Tokyo Chemical Industry Co., Ltd.) as a reaction catalyst were added thereto and reacted at 110° C. for 21 hours. The reaction solution was returned to room temperature and diluted with γ-butyrolactone to a solid content of 20% by mass, and the solution was filtered to obtain 274.2 g of a solution of a second resin having an epoxy group and a phenolic hydroxy group (N695OH70). The obtained reaction product had a number average molecular weight of 3,000, a weight average molecular weight of 7,500, and an epoxy equivalent of 2,200.

### Production Example 7

### Production of a Second Resin having an Epoxy Group and a Phenolic Hydroxy Group (N770OH50)

259.9 g of a solution of a second resin having an epoxy group and a phenolic hydroxy group (N770OH50) was obtained in the same manner as in Production Example 5, except that 15.4 g of 3,5-dihydroxybenzoic acid was used. The obtained reaction product had a number average molecular weight of 2,000, a weight average molecular weight of 6,900, and an epoxy equivalent of 670.

### Production Example 8

### Production of a Second Resin having an Epoxy Group and a Phenolic Hydroxy Group (N695OH50)

256.2 g of a solution of a second resin having an epoxy group and a phenolic hydroxy group (N695OH50) was obtained in the same manner as in Production Example 6, except that 13.9 g of 3,5-dihydroxybenzoic acid was used. The obtained reaction product had a number average molecular weight of 2,900, a weight average molecular weight of 6,400, and an epoxy equivalent of 820.

### Colorant (C)

As the colorant (C), a black dye, VALIFAST® BLACK 3804 (a black dye defined by the C.I. as solvent black 34, manufactured by Orient Chemical Industries Co., Ltd.), NUBIAN® BLACK PA-2802 (a mixture of a black dye defined by the C.I. as solvent black 27 and an oil-soluble dye, manufactured by Orient Chemical Industries Co., Ltd.), or VALIFAST® BLACK 3820 (a black dye defined by the C.I. as solvent black 27, manufactured by Orient Chemical Industries Co., Ltd.) was used.

### Photoacid Generator (D)

As the photoacid generator (D), PAI-101 (CAS No. 82424-53-1, manufactured by Midori Kagaku Co., Ltd.), which is an oxime-based photoacid generator, was used. PAI-101 generates p-toluenesulfonic acid (pKa=−2.8) by light irradiation. The structure of PAI-101 is shown below.

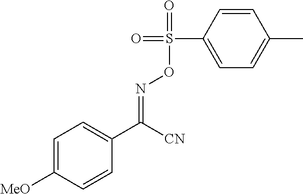 [SMILES: COc1ccc(/C(C#N)=N/OS(=O)(=O)c2ccc(C)cc2)cc1]

As the photoacid generator (D), PAG-103 (2-[2-(propylsulfonyloxyimino)thiophen-3(2H)-ylidene]-2-(2-methylphenyl)acetonitrile, manufactured by BASF, CAS No. 852246-55-0), which is an oxime-based photoacid generator, was used. PAG-103 generates 1-propanesulfonic acid (pKa=−2.8) by light irradiation. The structure of PAG-103 is shown below.

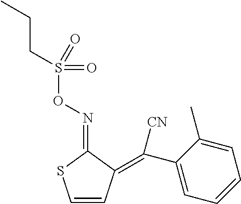 [SMILES: CCCS(=O)(=O)O/N=C1\SC=C\C1=C(\C#N)c1ccccc1C]

As the photoacid generator (D), PAG-169 (manufactured by BASF), which is an oxime-based photoacid generator, was used. PAG-169 generates trifluoromethanesulfonic acid (pKa=−13) by light irradiation.

TS-150A (ester of 4,4′-[1-[4-[1-(4-hydroxyphenyl)-1-methylethyl]phenyl]ethylidene]bisphenol (TrisP-PA) with 6-diazo-5,6-dihydro-5-oxonaphthalene-1-sulfonic acid (1,2-naphthoquinone diazide-5-sulfonic acid), manufactured by Toyo Gosei Co., Ltd.) was used as a quinone diazide compound. The structure of TS-150A is shown below.

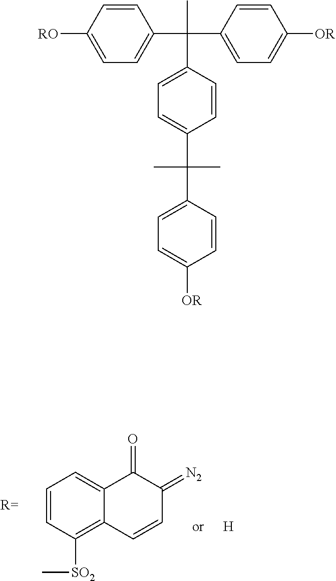

Phloroglucinol or 2,4-dihydroxybenzoic acid was used as the dissolution accelerator (E).

Megaface® F-559 (a fluorosurfactant, manufactured by DIC Corporation) was used as the surfactant (leveling agent).

A mixed solvent of γ-butyrolactone (GBL) and propylene glycol monomethyl ether acetate (PGMEA) (GBL:PGMEA=40:60 (mass ratio) or GBL:PGMEA=70:30 (mass ratio)) was used as the solvent (G).

PCX-02e of Reference Production Example 1, GMA-MAA of Reference Production Example 2, EPICLON® N-770 (phenol novolak epoxy resin, manufactured by DIC Corporation, epoxy equivalent: 188), and SHONOL® BRG-556 (phenol novolak resin, manufactured by Aica Kogyo Company, Limited) were used as other resins.

### (2) Evaluation Method

The evaluation methods used in Examples and Comparative Examples are described as follows.

### [OD Value After Heating]

The positive photosensitive resin composition was spin-coated on a glass substrate (size: 100 mm×100 mm×1 mm) so that the dry coating thickness was about 1.5 μm (Examples 1 to 13 and Comparative Examples 1 to 4) or about 3.8 μm (Examples 14 to 19), and heated on a hot plate at 120° C. for 80 seconds to dry the solvent. Thereafter, the coating was cured at 250° C. for 60 minutes under a nitrogen gas atmosphere to obtain a coating. The OD value of the cured coating was measured with a transmission densitometer (BMT-1, manufactured by Sakata Inx Eng. Co., Ltd.), corrected using the OD value of only glass, and converted to an OD value per μm of coating thickness. The thickness of the coating was measured using an optical film thickness measuring device (F20-NIR, manufactured by Filmetrics Japan, Inc.).

### [Solubility of Unexposed Part]

The positive photosensitive resin composition was bar-coated on a glass substrate (size: 100 mm×100 mm×1 mm) so that the dry coating thickness was 2.0 μm, and heated on a hot plate at 120° C. for 80 seconds to dry the solvent. After the dry coating thickness was measured using an optical film thickness measuring device (F20-NIR, manufactured by Filmetrics Japan, Inc.), the coating was subjected to alkali development using a spin development device (AD-1200, manufactured by Takizawa Sangyo K.K.) with an aqueous solution of 2.38% by mass of tetramethylammonium hydroxide for 60 seconds. The coating thickness after alkali development was measured again using the optical film thickness measuring device (F20-NIR, manufactured by Filmetrics Japan, Inc.), and the coating thickness (μm) dissolved during development was calculated as the solubility of the unexposed part.

### [Solubility of Exposed Part]

The positive photosensitive resin composition was bar-coated on a glass substrate (size: 100 mm×100 mm×1 mm) so that the dry coating thickness was 2.0 μm, and heated on a hot plate at 100° C. for 1 minute to carry out pre-baking. After the dry coating thickness was measured using an optical film thickness measuring device (F20-NIR, manufactured by Filmetrics Japan, Inc.), the coating was exposed at 100 mJ/cm² using an exposure apparatus (trade name Multilight ML-251A/B, manufactured by Ushio Inc.), in which an ultrahigh pressure mercury lamp was incorporated, through a bandpass filter for mercury lamp exposure (trade name HB0365, manufactured by Asahi Spectra Co., Ltd.) and a quartz photomask (having a line and space (L/S) pattern of 5 μm, 10 μm, 20 μm, 50 μm, 100 μm, 200 μm, or 500 μm). The exposure dose was measured using an accumulated UV meter (trade name UIT-150, light receiving unit UVD-S365, manufactured by Ushio Inc.). After the exposure, PEB was carried out by heating on a hot plate at 100° C. or 120° C. for 3 minutes or 5 minutes. Thereafter, alkali development was carried out using a spin development device (AD-1200, manufactured by Takizawa Sangyo K.K.) with an aqueous solution of 2.38% by mass of tetramethylammonium hydroxide for 60 seconds. The coating thickness after alkali development was measured again using the optical film thickness measuring device (F20-NIR, manufactured by Filmetrics Japan, Inc.), and the coating thickness (μm) dissolved during development was calculated as the solubility of the exposed part.

### [Solubility Difference]

A solubility difference (μm) was obtained by subtracting the solubility of the unexposed part (μm) from the solubility of the exposed part (μm). The larger the solubility difference, the higher the sensitivity, which means that the pattern formability is excellent.

### [10 μm Hole Pattern Formability]

The positive photosensitive resin composition was bar-coated on a glass substrate (size 100 mm×100 mm×1 mm) so that the dry coating thickness was 3.8 μm, dried under vacuum for 90 seconds, and then heated on a hot plate with a lid at 110° C. for 2 minutes to carry out pre-baking. The coating was exposed at 100 mJ/cm² or less using an exposure apparatus (trade name Multilight ML-251A/B, manufactured by Ushio Inc.), in which an ultrahigh pressure mercury lamp was incorporated, through a bandpass filter for mercury lamp exposure (trade name HB0365, manufactured by Asahi Spectra Co., Ltd.) and a quartz photomask (having a φ20 μm pattern). The exposure dose was measured using an accumulated UV meter (trade name UIT-150, light receiving unit UVD-S365, manufactured by Ushio Inc.). After the exposure, PEB was carried out by heating on a hot plate with a lid at 115 to 130° C. for 3 minutes or 4 minutes. Thereafter, alkali development was carried out using a spin development device (AD-1200, manufactured by Takizawa Sangyo K.K.) with an aqueous solution of 2.38% by mass of tetramethylammonium hydroxide for 60 seconds. Further, the coating was cured in an inert oven (DN411I, manufactured by Yamato Scientific Co., Ltd.) by heating at 250° C. for 60 minutes. The coating thickness of the cured coating was measured using an optical film thickness measuring device (F20-NIR, manufactured by Filmetrics Japan, Inc.), and the formed hole was observed using a microscope (VHX-6000, manufactured by Keyence Corporation). The case where a coating thickness was 3.0 μm or more and a hole diameter was 10 μm or more was judged as good, and the case where a coating thickness was 2.9 μm or less, or a hole diameter was 9 μm or less was judged as defective.

### [Step Pattern Formability]

The positive photosensitive resin composition was bar-coated on a glass substrate (size 100 mm×100 mm×1 mm) so that the dry coating thickness was 3.8 μm, dried under vacuum for 90 seconds, and then heated on a hot plate with a lid at 110° C. for 2 minutes to carry out pre-baking. The coating was exposed at 100 mJ/cm² or less using an exposure apparatus (trade name Multilight ML-251A/B, manufactured by Ushio Inc.), in which an ultrahigh pressure mercury lamp was incorporated, through a bandpass filter for mercury lamp exposure (trade name HB0365, manufactured by Asahi Spectra Co., Ltd.) and a quartz half-tone photomask (having a hole having a transmittance of 100% and a diameter of 10.5 μm in the center, and an annular pattern surrounding the hole, the pattern having a transmittance of 25%, an outer diameter of 30.5 μm, and a width of 10 μm). The exposure dose was measured using an accumulated UV meter (trade name UIT-150, light receiving unit UVD-S365, manufactured by Ushio Inc.). After the exposure, PEB was carried out by heating on a hot plate with a lid at 110 to 130° C. for 3 minutes or 4 minutes. Thereafter, alkali development was carried out using a spin development device (AD-1200, manufactured by Takizawa Sangyo K.K.) with an aqueous solution of 2.38% by mass of tetramethylammonium hydroxide for 60 seconds. Further, the coating was cured in an inert oven (DN411I, manufactured by Yamato Scientific Co., Ltd.) by heating at 250° C. for 60 minutes. The step pattern formed on the cured coating was observed using a shape analyzing laser microscope (trade name VK-X200, manufactured by Keyence Corporation), and the case where the step width was 20 μm or more was judged as good, and the case where the step width was less than 20 μm was judged as defective.

### (3) Preparation and Evaluation of Positive Photosensitive Resin Compositions

### Examples 1 to 13, and Comparative Examples 1 to 4

In accordance with the composition described in Table 1 or Table 2, the first resin (A), the second resin (B), and optionally other resins (optional component (F)) were mixed and dissolved, and to the obtained solution, the colorant (C), the photoacid generator (D), and the quinone diazide compound (optional component (F)), the dissolution accelerator (E), the surfactant (optional component (F)), and the GBL/PGMEA mixed solvent (G) described in Table 1 or

Table 2 were added, and the mixture was further mixed. After visually confirming that the components were dissolved, the mixture was filtered through a millipore filter having a pore diameter of 0.22 μm to prepare a positive photosensitive resin composition having a solid concentration of 12% by mass. The parts by mass of the composition in Table 1 and Table 2 is a converted value in terms of solid content. Table 1 and Table 2 also describe the protection ratio of the phenolic hydroxy groups of the first resin (A) with respect to the total of the alkali-soluble functional groups of the first resin (A) and the second resin (B). Evaluation results of the positive photosensitive resin compositions of Examples 1 to 9 and Comparative Examples 1 to 2 are shown in Table 1. Evaluation results of the positive photosensitive resin compositions of Examples 10 to 13 and Comparative Examples 3 to 4 are shown in Table 2.

TABLE 1
(compositions are provided in parts by mass)

| | | | | Ex. 1 | Ex. 2 | Ex. 3 | Ex. 4 | Ex. 5 | Ex. 6 |
|---|---|---|---|---|---|---|---|---|---|
| Composition | First resin (A) | | PCX-02e-EOE | 54 | 45 | 40 | 34 | — | 35 |
| | | | PCX-02e-Boc | — | — | — | — | 37 | — |
| | Second resin (B) | | N770OH70 | 12 | 18 | 20 | 20 | 20 | — |
| | | | N695OH70 | — | — | — | — | — | 22 |
| | Colorant (C) | | VALIFAST ® | 27 | — | — | — | — | — |
| | | | BLACK 3804 | | | | | | |
| | | | NUBIAN ® | — | 30 | 30 | 31 | 31 | 31 |
| | | | BLACK PA-2802 | | | | | | |
| | Photoacid generator (D) | | PAI-101 | 7.0 | 7.0 | 10 | 15 | 10 | 10 |
| | Dissolution accelerator (E) | | Phloroglucinol | — | — | — | — | — | 2.0 |
| | | | 2,4-Dihydroxybenzoic | — | — | — | — | — | — |
| | | | acid | | | | | | |
| | Optional | Surfactant | F-559 | 0.14 | 0.14 | 0.14 | 0.14 | 0.14 | 0.14 |
| | component (F) | Other resins | PCX-02e | — | — | — | — | — | — |

| | Solvent (G) | GBL:PGMEA = 40:60 | 733 | 733 | 733 | 733 | 733 | 733 |
|---|---|---|---|---|---|---|---|---|
| | | (mass ratio) | | | | | | |
| | Protection rate of (A) based on the total of alkali- | | 51 | 44 | 40 | 38 | 19 | 28 |
| | soluble functional groups of (A) and (B) (mol %) | | | | | | | |
| Film | Pre-baking conditions | Temperature [° C.] | 100 | 100 | 100 | 100 | 100 | 120 |
| formation | | Time [min] | 1 | 1 | 1 | 1 | 1 | 1 |
| conditions | Exposure dose [mJ/cm²] | | 100 | 100 | 100 | 100 | 100 | 100 |
| | PEB conditions | Temperature [° C.] | 100 | 120 | 120 | 120 | 120 | 120 |
| | | Time [min] | 3 | 3 | 5 | 3 | 3 | 5 |

| | | | | | | | |
|---|---|---|---|---|---|---|---|
| Evaluation | OD value after heating [/1 μm] | 1.00 | 1.00 | 0.98 | 1.06 | 1.03 | 1.12 |
| results | Solubility of exposed part [μm] | 1.05 | 0.79 | 1.07 | 2.00 | 1.23 | 1.44 |
| | Solubility of unexposed part [μm] | 0.41 | 0.08 | 0.13 | 0.10 | 0.74 | 0.10 |
| | Solubility difference [μm] | 0.64 | 0.71 | 0.94 | 1.90 | 0.49 | 1.34 |

| | | | | | | | Comp. | Comp. |
|---|---|---|---|---|---|---|---|---|
| | | | | Ex. 7 | Ex. 8 | Ex. 9 | Ex. 1 | Ex. 2 |
| Composition | First resin (A) | | PCX-02e-EOE | 37 | 37 | 39 | — | 59 |
| | | | PCX-02e-Boc | — | — | — | — | — |
| | Second resin (B) | | N770OH70 | 20 | 20 | 20 | 20 | — |
| | | | N695OH70 | — | — | — | — | — |
| | Colorant (C) | | VALIFAST ® | — | — | — | — | — |
| | | | BLACK 3804 | | | | | |
| | | | NUBIAN ® | 31 | 31 | 31 | 31 | 31 |
| | | | BLACK PA-2802 | | | | | |
| | Photoacid generator (D) | | PAI-101 | 10 | 10 | 10 | 10 | 10 |
| | Dissolution accelerator (E) | | Phloroglucinol | 2.0 | — | — | — | — |
| | | | 2,4-Dihydroxybenzoic | — | 2.0 | — | — | — |
| | | | acid | | | | | |
| | Optional | Surfactant | F-559 | 0.14 | 0.14 | 0.14 | 0.14 | 0.14 |
| | component (F) | Other resins | PCX-02e | — | — | — | 39 | — |

| | Solvent (G) | GBL:PGMEA = 40:60 | 733 | 733 | 733 | 733 | 733 |
|---|---|---|---|---|---|---|---|
| | | (mass ratio) | | | | | |
| | Protection rate of (A) based on the total of alkali- | | 39 | 39 | 40 | 0 | 65 |
| | soluble functional groups of (A) and (B) (mol %) | | | | | | |
| Film | Pre-baking conditions | Temperature [° C.] | 120 | 100 | 120 | 120 | 120 |
| formation | | Time [min] | 1 | 1 | 1 | 1 | 1 |
| conditions | Exposure dose [mJ/cm²] | | 100 | 100 | 100 | 100 | 100 |
| | PEB conditions | Temperature [° C.] | 120 | 100 | 120 | 120 | 120 |
| | | Time [min] | 3 | 3 | 3 | 3 | 3 |

| | | | | | | |
|---|---|---|---|---|---|---|
| Evaluation | OD value after heating [/1 μm] | 1.08 | 1.05 | 0.97 | 0.96 | 1.00 |
| results | Solubility of exposed part [μm] | 2.00 | 2.00 | 1.69 | 2.00 | 0.14 |
| | Solubility of unexposed part [μm] | 0.13 | 0.07 | 0.04 | 2.00 | 0.01 |
| | Solubility difference [μm] | 1.87 | 1.93 | 1.65 | 0.00 | 0.13 |

TABLE 2
(compositions are provided in parts by mass)

| | | | | | | | | Comp. | Comp. |
|---|---|---|---|---|---|---|---|---|---|
| | | | | Ex. 10 | Ex. 11 | Ex. 12 | Ex. 13 | Ex. 3 | Ex. 4 |
| Composition | First resin (A) | | PCX-02e-EOE | — | — | 38 | — | — | — |
| | | | PCX-02e-THF | 37 | — | — | 37 | 37 | 37 |
| | | | PCX-02e-POE | — | 37 | | — | — | — |
| | Second resin (B) | | N770OH70 | 20 | 20 | 22 | 20 | — | — |
| | Colorant (C) | | NUBIAN ® | 31 | 31 | 31 | 31 | 31 | 31 |
| | | | BLACK PA-2802 | | | | | | |
| | Photoacid generator (D) | | PAI-101 | 10 | 10 | — | — | — | — |
| | | | PAG-103 | — | — | 7.0 | 5.0 | — | — |
| | Dissolution accelerator (E) | | Phloroglucinol | 2.0 | 2.0 | 2.0 | 2.0 | 2.0 | 2.0 |
| | Optional | Surfactant | F-559 | 0.14 | 0.14 | 0.14 | 0.14 | 0.14 | 0.14 |
| | component (F) | Other resins | GMA-MAA | — | — | — | — | 20 | — |
| | | | N-770 | — | — | — | — | — | 4.0 |
| | | | BRG-556 | — | — | — | — | — | 16 |
| | | Quinone diazide | TS-150A | — | — | — | 5.0 | 10 | 10 |

| | Solvent (G) | GBL:PGMEA = 40:60 | 733 | 733 | 733 | 733 | 733 | 733 |
|---|---|---|---|---|---|---|---|---|
| | | (mass ratio) | | | | | | |
| | Protection rate of (A) based on the total of alkali- | | 34 | 29 | 38 | 34 | 27 | 27 |
| | soluble functional groups of (A) and (B) (mol %) | | | | | | | |
| Film | Pre-baking conditions | Temperature [° C.] | 120 | 120 | 120 | 120 | 120 | 120 |
| formation | | Time [min] | 1 | 1 | 1 | 1 | 1 | 1 |
| conditions | Exposure dose [mJ/cm²] | | 100 | 100 | 100 | 100 | 100 | 100 |
| | PEB conditions | Temperature [° C.] | 120 | 120 | 120 | 120 | 120 | 120 |
| | | Time [min] | 3 | 3 | 3 | 3 | 3 | 3 |

| | | | | | | | |
|---|---|---|---|---|---|---|---|
| Evaluation | OD value after heating [/1 μm] | 1.05 | 1.07 | 1.05 | 1.09 | 1.08 | 1.08 |
| results | Solubility of exposed part [μm] | 2.00 | 2.00 | 1.83 | 1.92 | 0.45 | 0.30 |
| | Solubility of unexposed part [μm] | 0.08 | 0.11 | 0.10 | 0.05 | 0.05 | 0.00 |
| | Solubility difference [μm] | 1.92 | 1.89 | 1.73 | 1.87 | 0.40 | 0.30 |

### Example 14 to 19

In accordance with the composition described in Table 3, the first resin (A) and the second resin (B) were mixed and dissolved, and to the obtained solution, the colorant (C), the photoacid generator (D), the dissolution accelerator (E), and the GBL/PGMEA mixed solvent (G) described in Table 3 were added, and the mixture was further mixed. After visually confirming that the component was dissolved, the mixture was filtered through a millipore filter having a pore diameter of 0.22 μm to prepare a positive photosensitive resin composition having a solid concentration of about 12% by mass. The parts by mass of the composition in Table 3 is a converted value in terms of solid content. Table 3 also describes the protection ratio of the phenolic hydroxy groups of the first resin (A) with respect to the total of the alkali-soluble functional groups of the first resin (A) and the second resin (B), and the epoxy equivalent of the second resin (B). Evaluation results of the positive photosensitive resin compositions of

Examples 14 to 19 are shown in Table 3.

TABLE 3
(compositions are provided in parts by mass)

| | | | Ex. 14 | Ex. 15 | Ex. 16 | Ex. 17 | Ex. 18 | Ex. 19 |
|---|---|---|---|---|---|---|---|---|
| | First resin (A) | PCX-02e-THF | 33 | 33 | 33 | 38 | 38 | 33 |
| | Second resin (B) | N770OH50 | 17 | — | — | — | — | — |
| | | N695OH50 | — | 17 | — | — | — | — |
| | | N770OH70 | — | — | 17 | 22 | 22 | — |
| | | N695OH70 | — | — | — | — | — | 17 |
| | Colorant (C) | VALIFAST ® | 41 | 41 | 41 | 29 | 29 | 41 |
| | | BLACK 3820 | | | | | | |
| | Photoacid generator (D) | PAG-169 | 3.0 | 3.0 | 3.0 | 7.0 | — | 3.0 |
| | | PAG-103 | — | — | — | — | 7.0 | — |
| | Dissolution accelerator (E) | Phloroglucinol | 6.0 | 6.0 | 6.0 | 4.0 | 4.0 | 6.0 |
| | Solvent (G) | GBL:PGMEA = 70:30 | 100 | 100 | 100 | 100 | 100 | 100 |
| | | (mass ratio) | | | | | | |
| | Protection rate of (A) based on the total of alkali- | | 34 | 35 | 31 | 29 | 29 | 32 |
| | soluble functional groups of (A) and (B) (mol %) | | | | | | | |
| | Epoxy equivalent of (B) | | 670 | 820 | 2000 | 2000 | 2000 | 2200 |
| Film | Pre-baking conditions | Temperature [° C.] | 110 | 110 | 110 | 110 | 110 | 110 |
| formation | | Time [min] | 120 | 120 | 120 | 120 | 120 | 120 |
| conditions | Exposure dose [mJ/cm²] | | 90 | 90 | 60 | 50 | 150 | 60 |
| | PEB conditions | Temperature [° C.] | 130 | 130 | 120 | 115 | 110 | 120 |
| | | Time [min] | 4 | 4 | 4 | 3 | 3 | 4 |

| | | | | | | | |
|---|---|---|---|---|---|---|---|
| Evaluation | OD value after heating [/1 μm] | 1.00 | 1.00 | 1.00 | 0.90 | 0.90 | 1.00 |
| results | 10 μm hole pattern formability | Good | Good | Good | Good | Defective | Good |
| | Step pattern formability | Good | Good | Defective | Defective | Good | Defective |

### INDUSTRIAL APPLICABILITY

The positive photosensitive resin composition according to the present disclosure can be suitably used in radiation lithography for forming barrier ribs or an insulating film of an organic EL element. Organic EL elements provided with barrier ribs or an insulating film formed by using the positive photosensitive resin composition according to the present disclosure is suitably used as an electronic component in a display device exhibiting high contrast.

1. A positive photosensitive resin composition comprising a first resin (A) having a plurality of phenolic hydroxy groups, at least some of the plurality of phenolic hydroxy groups protected by an acid-decomposable group; a second resin (B) having an epoxy group and a phenolic hydroxy group; at least one colorant (C) selected from the group consisting of a black dye and a black pigment; and a photoacid generator (D).

2. The positive photosensitive resin composition according to claim 1, wherein the first resin (A) is an aqueous alkaline solution-soluble copolymer of a polymerizable monomer having a phenolic hydroxy group and an additional polymerizable monomer, the copolymer having a plurality of phenolic hydroxy groups, at least some of the plurality of phenolic hydroxy groups protected by the acid-decomposable group.

3. The positive photosensitive resin composition according to claim 1, wherein the acid-decomposable group of the first resin (A) is a 1-alkoxyalkyl group.

4. The positive photosensitive resin composition according to claim 2, wherein the first resin (A) has a structural unit represented by formula (3) 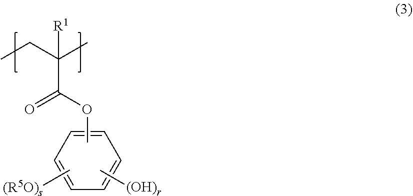
wherein in formula (3), R¹ is a hydrogen atom or an alkyl group having 1 to 5 carbon atoms, R⁵ is the acid-decomposable group, r is an integer from 0 to 5, s is an integer from 0 to 5, provided that r+s is an integer from 1 to 5, and the first resin (A) has at least one of the structural units in which s is an integer of 1 or more.

5. The positive photosensitive resin composition according to claim 2, wherein the first resin (A) has a structural unit represented by formula (2) 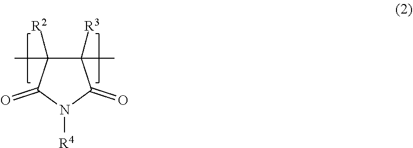
wherein in formula (2), R² and R³ are each independently a hydrogen atom, an alkyl group having 1 to 3 carbon atoms, a fully or partially fluorinated alkyl group having 1 to 3 carbon atoms, or a halogen atom, and R⁴ is a hydrogen atom, a linear alkyl group having 1 to 6 carbon atoms or a cyclic alkyl group having 4 to 12 carbon atoms, a phenyl group, or a phenyl group substituted with at least one selected from the group consisting of a hydroxy group, an alkyl group having 1 to 6 carbon atoms, and an alkoxy group having 1 to 6 carbon atoms.

6. The positive photosensitive resin composition according to claim 1, wherein 10 mol % to 95 mol % of the phenolic hydroxy groups of the first resin (A) are protected with the acid-decomposable group.

7. The positive photosensitive resin composition according to claim 1, wherein 5 mol % to 65 mol % of the phenolic hydroxy groups of the first resin (A) are protected with the acid-decomposable group with respect to the total of the alkali-soluble functional groups of the first resin (A) and the second resin (B).

8. The positive photosensitive resin composition according to claim 1, comprising 20% by mass to 90% by mass of the first resin (A) with respect to the total mass of the first resin (A) and the second resin (B).

9. The positive photosensitive resin composition according to claim 1, comprising 10 parts by mass to 150 parts by mass of the colorant (C) with respect to 100 parts by mass of the total of the first resin (A) and the second resin (B).

10. The positive photosensitive resin composition according to claim 1, comprising 0.1 parts by mass to 85 parts by mass of the photoacid generator (D) with respect to 100 parts by mass of the total of the first resin (A) and the second resin (B).

11. The positive photosensitive resin composition according to claim 1, wherein the optical density (OD value) of a cured coating of the positive photosensitive resin composition is 0.5 or more per μm of coating thickness.

12. The positive photosensitive resin composition according to claim 1, wherein the second resin (B) is a compound which is a reaction product of a compound having at least two epoxy groups per molecule and a hydroxybenzoic acid compound and has a structure represented by formula (5) 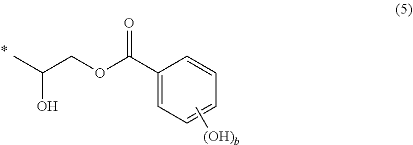
wherein in formula (5), b is an integer from 1 to 5, * represents a bonding site with the residue derived by removing an epoxy group involved in the reaction of the compound having at least two epoxy groups per molecule.

13. The positive photosensitive resin composition according to claim 12, wherein the compound having at least two epoxy groups per molecule is a novolak epoxy resin.

14. The positive photosensitive resin composition according to claim 12, wherein the hydroxybenzoic acid compound is a dihydroxybenzoic acid compound.

15. The positive photosensitive resin composition according to claim 1, wherein the epoxy equivalent of the second resin (B) is 300 to 1,800, and the photoacid generator (D) generates trifluoromethanesulfonic acid by light irradiation.

16. An organic EL element barrier rib comprising a cured product of the positive photosensitive resin composition according to claim 1.

17. An organic EL element insulating film comprising a cured product of the positive photosensitive resin composition according to claim 1.

18. An organic EL element comprising a cured product of the positive photosensitive resin composition according to claim 1.
